(19) United States
(12) Patent Application Publication
(10) Pub. No.: US 2026/0352232 A1
(43) Pub. Date: Nov. 5, 2026

(54) Generalized Implicit Transmission

(71) Applicant: Muhammad Ahsan Naim, Irving, TX (US)

(72) Inventor: Muhammad Ahsan Naim, Irving, TX (US)

(21) Appl. No.: 19/739,649

(22) Filed: Jul. 13, 2026

Related U.S. Application Data
(63) Continuation of application No. 18/924,821, filed on Oct. 23, 2024.
Application No. 18/924,821 is a continuation-in-part of application No. 18/473,687, filed on Sep. 25, 2023, now abandoned.
(60) Provisional application No. 63/409,598, filed on Sep. 23, 2022.
(60) Provisional application No. 63/592,457, filed on Oct. 23, 2023.

(51) Int. Cl. H03M 13/11; H03M 13/39

(52) U.S. Cl. CPC H03M 13/1108; H03M 13/3977

(57) ABSTRACT

Link capacity or data rate on a wired or wireless communication link such as WiFi, 5G, 6G, etc. may be increased by using two implicit transmission techniques, namely, implicit transmission with bit flipping (ITBF) and implicit transmission with collection decoding (ITCD) to transmit an independent second coded sequence implicitly while transmitting a first coded sequence explicitly over the channel. For instance, a novel generalized implicit transmission (GIT) technique that can transmit any number of independent implicit sequences implicitly while transmitting a single explicit sequence over the channel may be utilized, and GIT with multiple implicit sequences can increase the transmission rate significantly.

### CROSS-REFERENCE TO RELATED APPLICATIONS

This application is a continuation of U.S. patent application Ser. No. 18/924,821, filed on Oct. 23, 2024, and entitled “Generalized Implicit Transmission,” the contents of which are incorporated herein by reference in their entirety.

In turn, U.S. patent application Ser. No. 18/924,821 claims priority under 35 U.S.C. § 120 to and is a continuation-in-part of U.S. patent application Ser. No. 18/473,687, filed on Sep. 25, 2023, and entitled “Implicit Transmission of Coded Information,” which, in turn, claims priority to U.S. Provisional Patent Application No. 63/409,598, filed on Sep. 23, 2022, and entitled “Implicit Transmission of Coded Information.” The contents of each of these foregoing applications are incorporated herein by reference in their entireties.

Further, U.S. patent application Ser. No. 18/924,821 claims priority under 35 U.S.C. § 119 (e) to U.S. Provisional Patent Application No. 63/592,457, filed on Oct. 23, 2023, and entitled “Generalized Implicit Transmission,” the contents of which are incorporated herein by reference in their entirety.

### OVERVIEW

Disclosed herein is a novel collection of punctured codes decoding (CPCD) technique that considers a code as a collection of its punctured codes. Two forms of CPCD, serial CPCD that decodes each punctured code serially and parallel CPCD that decodes each punctured code in parallel, are discussed. In contrast to other modifications of LDPC decoding documented in the literature, the proposed CPCD technique views a LDPC code as a collection of punctured LDPC codes, where all punctured codes are derived from the original LDPC code by removing different portions of its parity bits. CPCD technique decodes each punctured code separately and exchanges extrinsic information obtained from that decoding among all other punctured codes for their decoding. Hence, as the iterations increase, the information obtained in the decoding of punctured codes improves making CPCD perform better than standard decoding.

Also disclosed herein is novel implicit transmission with bit flipping (ITBF) technique to transmit a coded stream implicitly while transmitting a coded stream explicitly over a channel. ITBF flips a set of chosen parity bits of the explicitly transmitted stream according to an implicit stream. Results obtained using the low density parity check (LDPC) code employed in the 5G standard show that ITBF can transmit an implicit stream up to 13.19% of the rate of transmission of the explicit stream without significantly sacrificing performance, or increasing the decoding complexity or the decoding delay. The ITBF is combined with collection of punctured code decoding (CPCD) to form implicit transmission with collection decoding (ITCD) schemes that can further increase the rate of transmission on the implicit stream without increasing the decoding delay, however, with a slight increase in the decoding complexity. It is demonstrated with the LDPC code in the WiFi standard that ITCD can transmit an implicit stream at up to 25% of the rate of transmission of the explicit stream.

Also disclosed herein is novel gradual initial decoding (GID) technique to improve implicit transmission with bit flipping (ITBF) and implicit transmission with collection decoding (ITCD) techniques. Further, two additional decoding techniques, namely, feedback implicit decoding (FID) and iterative implicit decoding (IID) are introduced for further improvement. It is demonstrated that all techniques in the present disclosure can significantly improve performance in implicit transmission and increase the transmission rate on the implicit sequence.

Also disclosed herein is novel generalized implicit transmission (GIT) technique that can transmit any number of independent implicit sequences implicitly while transmitting a single explicit sequence over the channel. The GIT technique, its encoding and decoding are explained in detail. It is demonstrated using the LDPC codes employed in the WiFi and 5G/6G standards that GIT with multiple implicit sequences can increase the transmission rate significantly higher than those that can be achieved with a single implicit sequence.

Also disclosed herein is a generalized implicit transmission (GIT) technique that can transmit multiple implicit sequences while transmitting a single explicit sequence over a channel. Instead of considering all sequences as independent sequences, this technique considers the explicit sequence and all implicit sequences of a GIT collectively as a single code referred to as a GIT coding scheme. The overall code rate Rₒᵥₑᵣₐₗₗ and the inherent coding gain achieved by a GIT coding scheme due to the transmission of information implicitly are discussed. A GIT coding scheme constructed from a rate R code to function as a rate Rₒᵥₑᵣₐₗₗ code, on average, transmits Rₒᵥₑᵣₐₗₗ/R number of codewords of a rate R code for every single codeword transmitted over the channel by transmitting (Rₒᵥₑᵣₐₗₗ−R)/R number of codewords over all implicit sequences. A simple way to convert existing practical codes into GIT coding schemes is also presented.

The results presented with the LDPC codes employed in the WiFi and the 5G standards demonstrate that GIT coding schemes can achieve very high coding gains over traditional codes while functioning as high rate codes. It is also demonstrated that GIT coding schemes can operate in the so-called unreachable region relative to the Shannon-Hartley bound.

### BRIEF DESCRIPTION OF THE DRAWINGS

The various features of the present disclosure are illustrated in the drawings listed below and described in the detailed description that follows.

FIG. 1 illustrates a Tanner graph for Quasi-cyclic (QC) LDPC codes.

FIG. 2 illustrates parallel and serial CPCD.

FIG. 3 illustrates an example structure of an ITBF transmitter.

FIG. 4 illustrates actions that may be taken by a bit flipping unit (BFU) when l=6.

FIG. 5 illustrates an example structure of an ITBF decoder.

FIG. 6 illustrates a generalized implicit encoding principle.

FIG. 7 illustrates an example implicit encoder block.

FIG. 8 illustrates a GIT encoding structure.

FIG. 9 illustrates an example GIT scheme.

FIG. 10 illustrates an example implicit decoder block.

FIG. 11 illustrates an example GIT decoding structure.

FIG. 12 illustrates decoding of codewords in the example shown in FIG. 9.

FIG. 13 illustrates variations of an overall code rate Rₒᵥₑᵣₐₗₗ with the number of implicit sequences N used in (a) scheme 1; (b) scheme 2; (c) scheme 3; and (d) scheme 4.

FIG. 14 illustrates a secure communication structure.

FIG. 15 illustrates an example message re-ordering unit.

FIG. 16 illustrates security enhancement with a GIT coding scheme.

FIG. 17 illustrates GIT encoding with interleavers.

FIG. 18 illustrates GIT decoding structure with interleavers.

### DETAILED DESCRIPTION

LDPC codes, first discovered by Gallager, are linear block codes that have a sparse parity check matrix. LDPC codes can approach the Shannon limit over many different channels using linear time complex decoding algorithms. Due to their superior performance and reasonable decoding complexity, LDPC codes have received significant interest in a variety of communication systems such as deep-space communication systems, wireless communication systems, optical communication systems, underwater acoustic communication systems, magnetic recording (MR) systems, neural networks and antenna systems. Further, LDPC codes have been adopted in different standards such as in 5G NR, IEEE802.11n, IEEE802.11ac, IEEE802.16e (Wi-MAX), 10G-BaseT Ethernet, and Digital Video Broadcasting (DVB).

Further, LDPC codes provide comparable or better performance than turbo codes with lower decoding complexity. In fact, the fifth-generation (5G) transmission is adopting LDPC codes for the data channel, moving away from turbo codes employed in the fourth generation (4G) standard.

LDPC codes are defined by their m×n parity check matrix H, where n is the codeword length and m is the number of parity check equations. In general, any LDPC code can have any number of parity check equations but only (n−k) of them will be linearly independent, where k is the number of message bits. Thus, rank₂ H=(n−k), where rank₂ H is the number of rows in H that are linearly independent over GF 2. In addition, LDPC codes can be represented by their Tanner graph (bipartite graph). A Tanner graph associated with H has m check nodes (CNs) corresponding to the set of parity check equations, and n variable nodes (VNs) corresponding to coded bits of the codeword. A CN j is connected to a VN i if the (j,i)th element hⱼᵢ is equal to 1.

Different construction methods of LDPC codes such as (pseudo) random and structured constructions of LDPC codes have been proposed in the literature. All the proposed LDPC codes have to follow important design criteria in order to achieve efficient encoding, near-capacity performance, and low error floor. Quasi-cyclic (QC) LDPC codes which exhibit advantages over other types of LDPC codes, have gained interest recently.

Different forms of hard and soft-decision decoding algorithms have been discussed for the decoding of LDPC codes. The soft-decision decoding algorithms are widely employed because of their superior performance over hard decision algorithms. Among the soft-decision decoding algorithms available for LDPC decoding, SPA decoding is known to provide the best possible performance that can be achieved by iterative decoding, however, at the expense of increased complexity and decoding delay that may be critical for some delay-sensitive applications. Thus, many alternative methods have been proposed to reduce the decoding complexity of SPA at the cost of performance. One of the well-known simpler decoding algorithms is the Min-Sum (MS) algorithm. Several modified versions of the MS algorithm have been proposed in order to recover the performance loss of MS decoding with respect to the SPA decoding.

In addition, decoding algorithms developed using super codes formed by dividing CNs into two or more disjoint groups and passing soft information among them have been presented. It has been shown that such methods can reduce the required memory. In decoding of each group employs all VNs and the portion of CNs associated with that group.

In the development of CPCD, instead of dividing CNs into groups, we choose to divide VNs into groups. The best way to follow this thought would be to have the entire message bits and a separate portion of the parity bits in each group. Hence, each group in CPCD that consists of the entire set of message bits and a separate portion of the parity bits would become a punctured code of the original CPCD code. Compared with groups that employ a portion of CNs and all VNs, punctured codes (groups) in CPCD employ a portion of VNs and all CNs. However, it is important to note that in CPCD, the decoding of each punctured code should be performed on the Tanner graph of the mother code in order to maintain the same parity check equations. As a result, decoding of each punctured code provides information of VNs other than those that belong to that punctured code. CPCD can perform better than the standard decoding of the mother code at the same or lower number of iterations.

Puncturing is one of the effective ways to achieve variable code rate by deleting selected bits (usually parity bits) of codewords before transmission. Many different puncturing methods for LDPC codes such as random puncturing, order puncturing, grouping and sorting program and puncturing with a puncturing matrix obtained by density evolution have been discussed in the literature.

In the present disclosure, a novel CPCD technique that views an LDPC code as a collection of several of its punctured codes by puncturing only the parity portion of the codeword is described. This view of LDPC codes allows the development of the CPCD technique that is demonstrated here to perform significantly better than standard SPA decoding of LDPC codes. Two different forms of CPCD, namely serial CPCD and parallel CPCD are discussed.

We next discuss the structure of QC LDPC codes followed by SPA decoding.

QC LDPC codes are known to have good error performance, high throughput and low latency with simplified hardware implementations. Due to their advantages and special structure, QC LDPC codes have been adopted in different standards including IEEE 802.16e, IEEE 802.11n and 5G standards. Thus, QC LDPC codes are considered throughout this disclosure.

The m×n parity-check matrix H of a QC LDPC code is constructed by a collection of z×z square circulant matrices P_{r(i,j)}, each of which is either zero or identity matrix with arbitrary shift (left or right) as shown in the following equation:

$$H = [ \begin{matrix}{P}_{{r}_{( 0 , 0 )}} & {P}_{{r}_{( 0 , 1 )}} & … \vert & {P}_{{r}_{( 0 , {n}_{b} - 1 )}} \\ {P}_{{r}_{( 1 , 0 )}} & {P}_{{r}_{( 1 , 1 )}} & … & {P}_{{r}_{( 1 , {n}_{b} - 1 )}} \\ ⋮ & ⋮ & ⋱ & ⋮ \\ {P}_{{r}_{( {m}_{b} - 1 , 0 )}} & {P}_{{r}_{( {m}_{b} - 1 , 1 )}} & … & {P}_{{r}_{( {m}_{b} - 1 , {n}_{b} - 1 )}}\end{matrix} ]$$

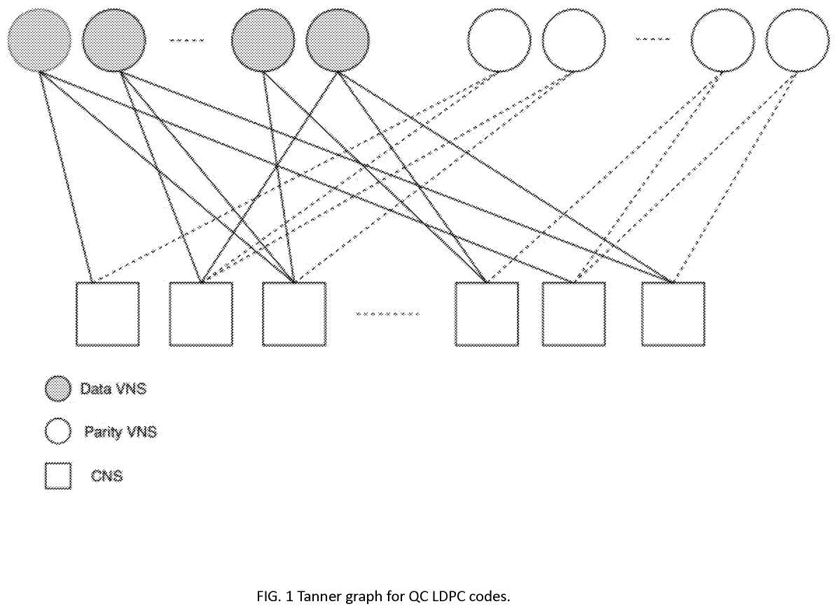

Therefore, m=zm_{b} is the number of rows and n=zn_{b} is the number of columns of H. As shown in FIG. 1, similar to any LDPC code, QC LDPC codes can also be represented by the Tanner graph which describes how the VNs are connected to their corresponding CNs. One of the advantages of QC LDPC is their inherent dual diagonal structure, which can be seen from the connections of VNs and CNs as illustrated in FIG. 1.

In accordance with the present disclosure, LDPC codes are iteratively decoded using the SPA. Each SPA iteration consists of two sequential steps: VN updates and CN updates until a stopping criterion is satisfied. Usually, the stopping criterion is met either when all parity check equations are satisfied or when a preselected maximum number of iterations has been reached.

In principle, the CPCD technique disclosed herein considers a code, which is referred to as the mother code, as a collection of its smaller punctured codes.

Simple Example: In order to describe the basic idea, let us consider a simple (7,1) repetitive code C, that repeats every message bit u six times, as the mother code. This mother code can be viewed as a combination of two (4,1) punctured codes; a first punctured code C₁ that represents the message bit and the first three parity bits, (u, p₁, p₂, p₃), and a second punctured code C₂ that represents the message bit and the last three parity bits, (u, p₄, p₅, p₆). By doing so, C₁ and C₂ can be separately decoded either in series or in parallel by considering them as punctured codes of the original (7,1) mother code. Both C₁ and C₂ can provide information about the message bit u and the parity bits of the other code in their respective decoding. Hence, when C₁ is soft decoded as a punctured code of the (7,1) mother code, it can provide extrinsic information about the message bit u and the parity bits u, p₄, p₅ and p₆ of C₂. Similarly, soft decoding of C₂ can provide extrinsic information of bits u, p₁, p₂ and p₃. The extrinsic information of C₂ (C₁), which includes both the message bit and its corresponding parity bits, provided in the decoding of C₁ (C₂) can be used as a-prior information in the decoding of C₂ (C₁). Therefore, an iterative decoding strategy can be developed to decode the mother code in terms of two or even a higher number of its punctured codes.

As will be appreciated, the above described (7,1) code has been chosen only as an example, and it should not be decoded iteratively as described above. Since the 7,1 code consists of only two codewords, it can be easily decoded in a maximum likelihood (ML) sense. However, the above described method is beneficial in the decoding of long codes such as LDPC codes that require iterative decoding as ML decoding is not feasible. It is further noticed in the above example that the parity bits of C₁ and C₂ can be chosen in any arbitrary manner from the six parity bits of the original mother code C. Further, if necessary, more than two punctured codes with a fewer number of parity bits can be similarly considered.

Based on the example described above, the CPCD technique can be applied to LDPC codes. Let us consider a general systematic (m,n) LDPC mother code C. In CPCD, the mother code is viewed as a collection of any D number of punctured codes, C₁, C₂, . . . , C_{D} by dividing the parity bits into D groups. Let u=(u₁, . . . uₖ) be the message sequence and p=(p₁, . . . , pₙ₋ₖ) be the corresponding parity sequence of C. Each punctured code C₁ contains the same message sequence u and a unique portion p, pₗ, where l=1, 2, . . . , D. Thus, it follows that p=Uₗpₗ. Let the number of parity bits in Cₗ be λₗ, therefore, the total number of parity bits

$${\sum }_{l = 1}^{D} {λ}_{l} = n - k .$$

Puncturing of an LDPC mother code can be done using any puncturing method to generate the set of D punctured codes. Regardless of the selected method of puncturing, it is generally desirable that puncturing is done so that every punctured code Cₗ, l=1, 2, . . . , D, satisfies the following two conditions: (a) as many CNs of C are still connected to the remaining VNs of Cₗ after puncturing and (b) the VNs that are connected to every CN of Cₗ has only a single punctured VN.

The first condition ensures that multiple punctured VNs should not be connected to the same CNs in order to make the recovery of the punctured nodes easier. Similarly, the second condition ensures that the punctured VNs have a low degree or equivalently few connections with CNs. As a result, these two conditions ensure that the effects of punctured bits of every punctured code Cₗ, l=1, 2, . . . , D, are felt by as many CNs as possible in the first half of every SPA iteration and those effects are then communicated back to the VNs, including those VNs of punctured bits, in the second half of every SPA iteration. However, it may not be possible to ensure that all punctured codes Cₗ can strictly satisfy these two conditions, but an attempt should be made to maintain them as much as possible. However, the above conditions can be fully satisfied by QC LDPC codes due to their dual-diagonal structure in the parity check matrix H.

In a system that employs CPCD, modifications are made only in the decoder while all other components of the system remain unchanged. The CPCD of LDPC codes modifies the standard SPA decoding according to the punctured code interpretation of the code described earlier. The task in CPCD is to recover the transmitted sequence u from the received version of the LDPC signal.

In the CPCD decoder, SPA iterative decoding is used by modifying the operations at the VNs. Every punctured code Cₗ, l=1, 2, . . . , D, uses the Tanner graph of the mother code C for its decoding. As it has been discussed in the literature, this is done by making the initial channel values of the punctured VNs zero due to the unavailability of the received signal of its punctured bits.

When SPA decoding of any punctured code Cₗ is performed on the Tanner graph of the mother code, the soft values of all punctured VNs also become available. Hence, every SPA iteration of any punctured code Cₗ, which are referred to as SPA sub-iterations, provides information for al message bits and parity bits of every other punctured code Cₜ, t≠l. Consequently, every SPA iteration consists of D SPA sub-iterations, one for each punctured code. The proposed CPCD technique is developed to run any single SPA sub-iteration of every punctured code by additionally using the most recent extrinsic information available from all other punctured codes. As a result, the modification to standard SPA decoding used in CPCD occurs in updating VNs at the beginning of every SPA sub-iteration of every punctured code Cₗ, l=1, 2, . . . , D.

Specifically, the operation at VNs is modified in every sub-iteration of the punctured code Cₗ by considering the (extrinsic) information provided by all other punctured codes Cₜ, t≠l as follows:

L(q_{i,j})ₗ=L(Xᵢ)ₗ+Σ_{j′∈Q}_{_{t\l}}L(r_{j′,i})ₗ

where, L(Xᵢ)ₗ represents all the extrinsic information of Cₗ provided by every other punctured codes Cₜ, l=1, 2, . . . , D t≠l as follows,

L(Xᵢ)ₗ=L(Xᵢ)ₗ+Σ_{t\l}Lₜₗ

where Lₜₗ=(LQi−L(cᵢ))ₜ is the extrinsic information of Cₗ obtained in the decoding of Cₜ.

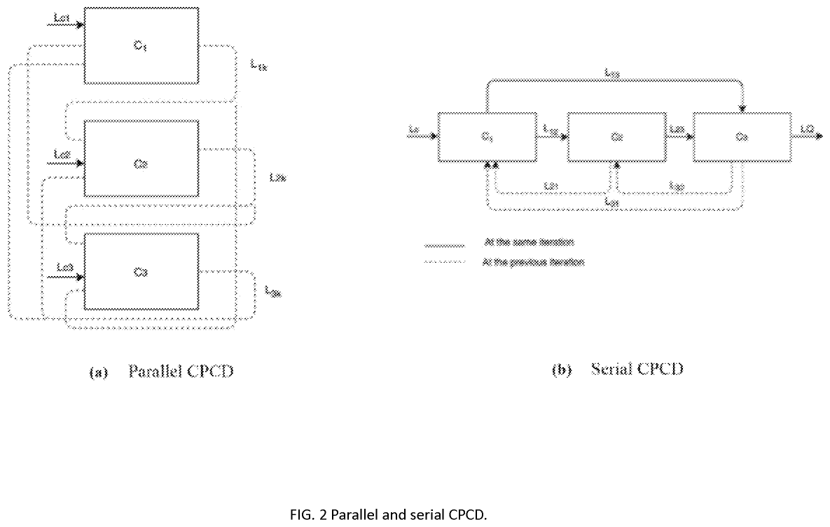

Since all punctured codes are separately decoded during sub-iterations, two separate implementations of CPCD, namely, (a) Serial CPCD that runs SPA sub-iterations in a serial manner every SPA iteration as illustrated in FIGS. 2a), and (b) Parallel CPCD that runs all D sub-iterations in a parallel manner in every SPA iteration as illustrated in FIG. 2b) are considered.

Therefore, in serial CPCD, in every lth sub-iteration of every sₜₕ SPA iteration, the information provided by the C₁, C₂, . . . . C₍ₗ₋₁₎ from the same sₜₕ iteration, and the information provided by C₍ₗ₊₁₎, C₍ₗ₊₂₎, . . . C_{D} from the immediately previous (s−1)th iteration are used to update the VNs. On the other hand, in parallel CPCD, during every sₜₕ SPA iteration, every sub-iteration uses information from all punctured codes from the (s−1)th iteration. During the first SPA iteration (s=1), all the information from the previous sub-iterations is assumed to be zero.

The decoder implementation depends on how the SPA sub-iterations run. Since all sub-iterations are running on the Tanner graph of the mother code, each sub-iteration is similar to a single SPA iteration in the standard SPA decoding. Therefore, serial CPCD runs SPA sub-iterations one at a time, whereas parallel CPCD requires to run D sub-iterations simultaneously. Therefore, serial CPCD requires only a single processor like standard SPA decoding while parallel CPCD requires D parallel processors. Subsequently, the implementation of serial CPCD does not increase the required processing power, but parallel CPCD increases the processing power by a factor D. In serial CPCD, since the information provided by all subsequent sub-iterations within any given SPA iteration is fed to the current sub-iteration, it is expected that serial CPCD would converge faster, which is supported by the numerical results presented later in the document. Even in parallel CPCD, since the information provided by all sub-iterations in the immediately previous SPA iteration is used in all sub-iterations within the current SPA iteration, the number of SPA iterations N can be expected to be slightly higher than that of serial CPCD but would be still comparable to it as seen from the numerical results presented later in the document.

Almost all current communication systems employ some form of error control coding to improve the reliability of transmission. LDPC codes, turbo codes, polar codes, etc. are commonly used in current systems. The studies so far have focused primarily on searching for good coding techniques and searching for good high-rate codes within those coding techniques. Studies have also focused on improving the decoding of coded signals to achieve good performance with low decoding complexity and decoding delay.

Instead of the traditional methods of searching for good codes, it is highly desirable to be able to transmit coded bits implicitly, without transmitting them physically over a channel, while transmitting a coded stream explicitly over that channel. It would be highly beneficial if such schemes can be developed without increasing the decoding complexity or the decoding delay while maintaining a significant data rate on the implicitly transmitted stream. If such implicit transmission methods can be developed, they can preferably be used with known powerful codes that have been derived using traditional methods.

Additionally in this disclosure, we introduce a scheme, referred to as implicit transmission with bit flipping (ITBF), to transmit a second coded stream (referred to here as the secondary stream or the implicit stream) implicitly without physically transmitting it over a channel during the transmission of a first coded stream (referred to here as the primary stream or the explicit stream) over that channel. In this disclosure, we present a simple way to transmit a secondary stream implicitly without significantly sacrificing the performance of the primary stream or increasing the decoding delay.

Implicit transmission has been proposed to transmit a turbo-coded implicit stream while transmitting a turbo-coded stream explicitly. There are other known techniques that use implicit transmission, such as spatial modulation (SM) and index modulation (IM). SM adds a new spatial domain using additional antennas to transmit additional information implicitly, while IM adds indices to the transmitted symbols to transmit additional information bits. Even though these schemes can transmit a stream implicitly, the decoding of the two streams need to be done jointly by running iterations between the explicit stream and the implicit stream. As a result, the receiver increases the decoding complexity and the decoding delay significantly. Specifically, these schemes demand an increase in the decoding complexity and the decoding delay by a factor of at least 6 to 10 due to the transmission of the implicit stream. Further, these schemes are: (a) dependent on the coding technique; it generates attractive schemes with turbo coded systems but fails with codes such as LDPC codes, (b) requires use of codes that are similar in coding power on the explicit and implicit streams due to the exchange of information between them during decoding.

Disclosed herein is a general ITBF method to transmit a secondary coded stream implicitly during the transmission of a primary coded stream explicitly. Throughout this disclosure, the primary stream is also referred to as the explicit stream while the secondary stream is also referred to as the implicit stream. In contrast to the IM and SM schemes, the proposed ITBF method here treats the explicit and the implicit streams independently. Therefore, ITBF does not require iterations that involve both the explicit and implicit streams and as a result, does not increase the decoding delay or significantly increase the decoding complexity.

In order to describe the ITBF technique, let us consider a code that generates n coded bits corresponding to every k message bits, where k<n. Then it is possible to choose l(<(n−k)) bits out of (n−k) parity bits that can be removed from the coded sequence and yet correctly recover the original message sequence of length k. These l bits can preferably be chosen by using a good known punctured code generated from code C. For example, let us consider a code C with rate ⅓, i.e., n=3 k. Then consider a rate ½ punctured code generated from that rate ⅓ code C. Note that in the construction of the rate ½ punctured code, n/6 coded bits of C are identified and removed. Hence, these n/6 coded bits can be selected as the l=n/6 coded bits of C. Of course, depending on the selected punctured code, the set of l coded bits and its length can change. Throughout this disclosure, these l bits are referred to as the chosen bits. Therefore, a set of chosen bits of a code C can be pre-selected by preferably considering a punctured code generated from the code C or by using any other method.

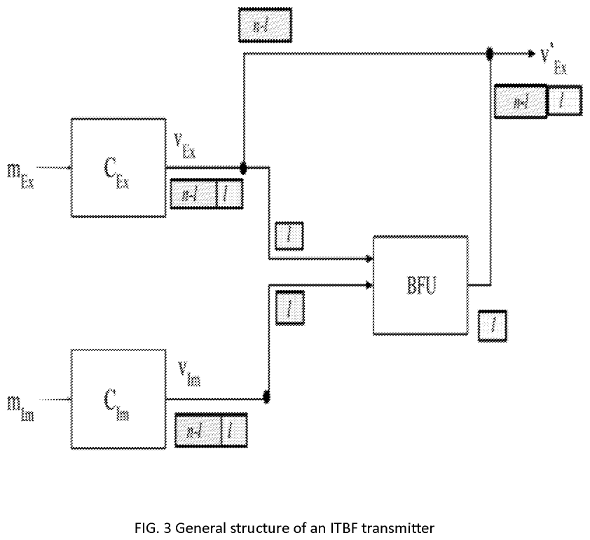

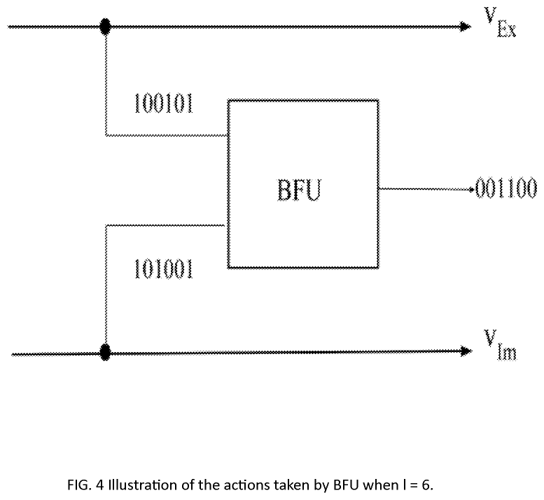

FIG. 3 illustrates the structure of the transmitter for the proposed ITBF scheme. In ITBF, an explicit message sequence mEx and an implicit message sequence m_{Im} are separately encoded according to two codes C_{Ex} and C_{Im} to generate two coded streams v_{Ex} and v_{Im} respectively. Without loss of generality, in this disclosure, we consider both C_{Ex} and C_{Im} to be the same code C, i.e., C_{Ex}=C_{Im}=C. However, as stated before, C_{Ex} and C_{Im} can be two independent codes. Then identify the 1 number of pre-selected chosen bit positions of v_{Ex}. Then, according to l bits of the coded implicit stream v_{Im}, flip the chosen bits of explicit coded stream v_{Ex} using a bit flipping unit (BFU) as illustrated in FIG. 3. Specifically, BFU flips each of these chosen bits of V_{Ex} if the corresponding coded bit of the implicit stream is a 1 (or a 0) and not flipped if the corresponding coded implicit bit is a 0 (or a 1). FIG. 4 illustrates an example of the flipping operation performed by the BFU when l=6. The resulting sequence v′_{Ex} on the explicit stream is then transmitted over the channel. Note that (a) the transmitted sequence v′_{Ex} and the coded sequence v_{Ex} have the same length n, (b) none of the coded bits of v_{Im} are transmitted over the channel, however, the effect of the corresponding l bits of v_{Im} that determined the flipping of the l chosen bits of v_{Ex}, is transferred by v′_{Ex}, and (c) following (a) and (b), the information of the explicit stream contained in v_{Ex} and the information of the corresponding l coded bits of v_{Im} are carried by v′_{Ex}. Therefore, upon transmitting ceil (n/l) number of blocks of v′_{Ex}, information of all coded bits of one full codeword of v_{Im} will be available allowing the receiver to decode a codeword of v_{Im}. Note also that, due to the flipping of the chosen bits, the transmitted sequence v_{Ex} may very well not be a valid coded sequence of C_{Ex}.

The proposed ITBF receiver disclosed herein is based on the following observation: Even though the transmitted sequence v′_{Ex} may not be a valid codeword of C_{Ex}, any existing invalidity is caused only within the l chosen bits due to the flipping of the bits that occurred prior to transmission. Therefore, if the received signal is initially decoded as a punctured code by ignoring those l chosen bits, the explicit message sequence mEx and the corresponding explicit coded sequence vEx can be correctly decoded. Further, this decoding provides information about the l chosen bits of v_{Ex} (without any flips) while the received signal provides information of v′_{Ex} (with the flips).

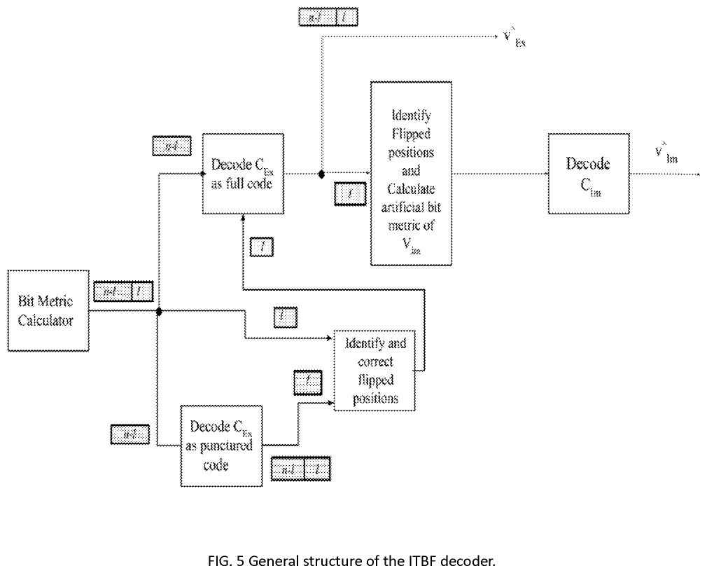

FIG. 5 shows the general structure of the ITBF decoder proposed here based on the above observation to recover both the explicit and the implicit streams. Below we explain the steps involved in ITBF decoding. In the discusison below, we focus primarily on the l chosen bits. In order to assist that discussion, we denote the following quantities of the l chosen bits:
(a) received signal values by y₁, y₂, . . . , yₗ,
(b) coded sequence values of v_{Ex} (prior to flipping) by v_{Ex1}, V_{Ex2}, . . . , V_{Ex1}, and
(c) transmitted sequence v′_{Ex} (after flipping) by v′_{Ex1}, V′_{Ex2}, . . . , v′_{Ex1}.

The decoding procedure may involve the following steps:
1) Initial Decoding: Initially, decode C as a punctured code by removing the l chosen bits from the received signal. If iterative decoding is used (such as in the decoding of a LDPC code), run initially a set of iterations of the punctured code. The number of initial iterations used for the punctured code can be pre-selected or adoptively varied depending on the signal to noise ratio or as the iterations progress. Note that the initial decoding also provide likelihood values of the l chosen bits, which are denoted here by L_{vEx(i)}, i=1, 2, . . . , l, and they represent the likelihood values of the encoded sequence V_{Ex} prior to flipping at the transmitter.
2) Detecting Flips: In order to decide whether or not each of the l chosen bits is flipped, hard decode each of the l chosen bits of v_{Ex}, which are denoted by bⁱ, i=1, 2, . . . , l, using the likelihood values of those bits found in step 1. Additionally, for each of the l chosen bits, hard decode the corresponding received signal value yⁱ, i=1, 2, . . . , l, to determine the hard decoded received signal value, yⁱₕ, i=1, 2, . . . , l that correspond to the flipped sequence v′_{Ex}. Then, using bⁱ and yⁱₕ values, determine fᵢ as

$${f}_{i} = \{ \begin{matrix}0 & {b}^{i} = {y}_{h}^{i} \\ 1 & {b}^{i} \neq {y}_{h}^{i}\end{matrix}$$

to indicate whether the ith bit was likely to have been flipped or not prior to transmission. Specifically, if fᵢ=0, the ith chosen bit is not likely to have been flipped while if fi=1, it is likely that the ith bit has been flipped. Note that fi values, which use the hard decoded received signals are corrupted by channel noise similar to a received signal.
3a) Since fi, i=1, 2, . . . , l, found in step 2, indicates whether or not the ith chosen bit has been flipped, it can then be used to modify the received sequence to correspond to vEx by reversing the effect of the flips for the decoding of the explicit stream. Specifically, the received signal yi can be corrected for the l chosen bits in the decoding of the explicit stream as (1−2fi)yi, i=1, 2, . . . , l.
3b) In case of iterative decoding, upon reversing the effects of the flips, continue decoding of C as a full code (not as a punctured code) by also including the corrected received signal values of the chosen bits.
4) Recall that the flipping of the l chosen bits were decided at the transmitter according to the implicit coded stream. Further, observe that if the ith implicit bit, Imᵢ, had actually been transmitted over the channel with the same noise experienced by yⁱ, it would have been received as (1−2Imi)|yi|. Hence, an artificially created received signal value can be obtained for each implicit coded bit Imi, i=1, 2, . . . , l as (1−2fi)|yi|. Note that depending on the value of fi (0 or 1), the artificially created channel value is positive or negative suggesting that the ith coded implicit bit has not been flipped or flipped respectively. Even though fi values are available after the initial decoding, a more reliable set of fi values can be calculated by using the LvEx(i) values at the end of the decoding of the explicit stream in step 3b. These re-calculated fi values can be used to calculate the artificially created received signal values for the corresponding l coded implicit bits. Since fi decisions are noisy, the artificially created received signal values of the Imᵢ, i=1, 2, . . . , l, are also noisy similar to channel information extracted from a noisy received signal. Therefore, in order to maintain good performance on the implicit stream, it is necessary to employ an error control code on the implicit stream similar to the explicit stream.

The first three steps describe the decoding of a single codeword of the explicit stream. It is noticed that if the initial decoding step 1 and the calculation of fᵢs in step 2 are reliable then step 3a would provide a reliable explicit stream that would perform almost as reliably as if no bits were flipped prior to transmission. It is also seen that when every codeword of the explicit stream (n coded bits) is transmitted over the channel, an artificially created channel information of l coded bits of the implicit stream can be extracted without transmitting any of those l bits over the channel.

If C is a small code, it can be decoded in a maximum likelihood (ML) sense in the initial decoding of C in step 1 and the decoding of C as a full code in step 3. However, this doubles the decoding complexity and the decoding delay of the explicit stream.

For a large code, such as an LDPC code and most other codes used in practice, ML decoding is not possible and instead iterative decoding is commonly used. In such situations, the initial decoding in step 1 and the full decoding in step 3b can be done in an efficient manner without increasing the overall decoding delay or the decoding complexity. Throughput this disclosure, the decoding delay is measured in terms of the total number of iterations while the decoding complexity is measured by the number of times the SPA algorithm is called during decoding thereby disregarding any delay or complexity added by the calculation of fᵢs and the correction of the flipped bits of the explicit stream. Focusing on the iterative decoding of C, a pre-selected N₁ number of iterations in step 1 and a pre-selected N₂ number of iterations in step 3b can be used. The values of N₁ and N₂ can be chosen to maintain the total number of iterations N=(N₁+N₂) close to the number of iterations commonly used without ITBF thereby maintaining about the same decoding delay and the decoding complexity.

The present disclosure will now explain how ITBF can be combined with CPCD to generate ITCD schemes that can transmit a higher data rate on the implicit stream than using ITBF alone while also improving performance on both explicit and implicit streams.

In CPCD, a code C (which is considered as the mother code) is viewed as a collection of a pre-selected number of D punctured codes, Ci, i=1, 2, . . . , D, generated from that mother code C. Considering C in systematic form, all n coded bits are viewed as a collection of the message bits and the set of its parity bits p. In CPCD, each punctured code Cᵢ is constructed from all message bits and a portion of the parity bits pᵢ, i=1, 2, . . . , D. In CPCD, pᵢs are formed by dividing all parity bits p into non-overlapping segments so that ∪pᵢ=p. During decoding, each Cᵢ is separately decoded by using the received signal corresponding to its own coded bits (message portion and its corresponding parity portion pi) and also using the extrinsic information of all bits of Cᵢ provided by the remaining punctured codes, Cⱼ, j=1, 2, . . . , D, i≠j.

ITBF uses a punctured code in the initial decoding (step 1). Therefore, the initial decoding in ITBF inherently consists of the following two punctured codes of C: (a) the punctured code used in the initial decoding (say C₁), and (b) the code formed by the message bits and the chosen bits that are not used in the initial decoding (say C₂). However, C₂ becomes available after performing decoding steps 1, 2 and 3a. Upon determining C₂, the decoding in ITBF was continued by considering C as a full code. Instead, decoding can be continued as in CPCD by considering C₁ and C₂ as two punctured codes. An ITBF scheme that switches to CPCD decoding after step 3a is considered as a hybrid ITBF/CPCD scheme or simply as an ITCD scheme. The block diagram of an ITCD decoder will be very similar to the ITBF decoder shown in FIG. 5 with the following two changes: (a) the “Decode C_{Ex} as a punctured code” block changed to “Decode C₁”, and (b) “Decode C_{Ex} as a full code” block changed to “Employ parallel CPCD with C₁ and C₂ as punctured codes.”

However, the CPCD technique considered in ITCD has differences between the CPCD technique discussed previously. In order to elaborate on the differences, let us first recall that all CPCD schemes described earlier typically use the same number of parity bits in all of their punctured codes and they all started to decode from the very first CPCD iteration. However, in ITBF, C₂ becomes available for decoding only after N₁ iterations to complete steps 1 through 3a, and further, the number of parity bits of C₂ is generally smaller than that of C₁. Therefore, in order to employ CPCD in ITBF, we first introduce three separate special types of CPCD as follows:
1. Unbalanced CPCD (U-CPCD) that employs different numbers of parity bits in different punctured codes.
2. Staggered CPCD (S-CPCD) that starts decoding different punctured codes at different numbers of CPCD iterations.
3. Unbalanced-staggered CPCD (US-CPCD) is a hybrid of U-CPCD and S-CPCD that employs different numbers of parity bits and starts decoding different punctured codes at different numbers of CPCD iterations.

In ITBF, the CPCD employed is the US-CPCD type of CPCD. Therefore, ITBF schemes switch to US-CPCD after completing steps 1 through 3a in the decoding of the first punctured code C₁. In general, if an ITCD scheme employs CPCD with D number of parallel punctured codes with N₁ number of initial decoding iterations followed by N₂ number of CPCD iterations, the decoding complexity would be increased, compared to SPA decoding, by a factor of (N₁+DN₂)/(N₁+N₂), however, without any increase in decoding delay.

To summarize, (a) ITBF can transmit a separate implicit coded stream without sacrificing any significant performance on both the explicit and implicit streams and (b) ITCD can transmit a higher data rate on the implicit stream while maintaining the same or better performance on both the explicit and implicit streams compared to traditional decoding of the explicit stream without any implicit stream.

ITBF and ITCD can be employed in any communication system to improve the overall transmission rate by transmitting a secondary coded stream implicitly. ITBF schemes can transmit a secondary coded stream implicitly without noticeably sacrificing performance while maintaining the same decoding delay and the decoding complexity. ITCD achieves the same goal as ITBF, but with a slight increase in decoding complexity. However, ITCD can maintain a higher data rate on the implicit stream while maintaining better or similar performance on both the implicit and explicit streams.

Since both explicit and implicit streams of both ITBF and ITCD schemes operate independently, different types of codes, different code rates, and desired BER values can be independently employed on the two streams. However, based on the common approach of identifying the chosen bits using a punctured code of the mother code, the proposed ITBF and ITCD techniques are more suitable for codes that can generate powerful punctured codes. However, it is important to note that codes employed in most applications, such as 5G NR and WiFi, have a rate adjustment feature which is usually implemented by puncturing the lowest rate code that has been chosen for the application. Therefore, codes employed in most applications are known to have powerful punctured codes. ITBF and ITCD techniques are highly attractive for multimedia applications. In multimedia applications, the explicit stream and the implicit stream can represent two different types of multimedia streams. For example, the explicit stream could transmit a video signal while the implicit stream transmits an audio signal thereby eliminating the need for a separate channel for the transmission of the audio signal.

Another important application of ITBF and ITCD is in information security. Different types of encryption methods are used in information security. The transmission of an independent implicit stream in ITBF and ITCD allows a secure communication system to add an additional layer of encryption through ITBF or ITCD.

For ITBF and ITCD schemes to perform well, it is generally necessary for the initial decoding step in the decoder to provide reliable information. Earlier in the present disclosure, it was described that after a pre-selected number of initial iterations, all chosen bits are resolved based on the likelihood values of those chosen bits at that point. However, since some of the chosen bits may not have correctly been decoded at that point, trying to resolve all chosen bits after that fixed number of initial iterations may not be the best approach. With that in mind, we propose here a gradual initial decoding (GID) approach to improve the initial decoding step in the decoding of ITBF and ITCD schemes. Theoretically, iterative decoding numerically searches for the optimal solution to a discrete convex optimization problem. It is well known that gradual adjustments during a numerical search enhance the chances of reaching that optimal solution. As a result, GID presented here which makes changes gradually can be expected to outperform initial decoding described earlier, which is referred to here as ID. Specifically, GID only resolves chosen bits as they become more reliable as the iterations progress. In this study, GID considers chosen bits to be reliable when the sign of their likelihood values remains unchanged over a pre-selected number of 2 previous iterations. In addition, GID considers the following pre-selected parameters:
Nₐ—the iteration number at which GID starts resolving chosen bits (Nₐ≥λ)
N_{b}—the iteration number at which GID stops resolving chosen bits (N_{b}≥Nₐ)
N_{c}—the number of iterations that ITBF decodes C as a full code considering all corrected chosen bits
N_{d}—the number of initial iterations that ITCD schemes complete before starting CPCD iterations (Nₐ≤N_{d}≤N_{b}).
Nₑ—the number of iterations used by each punctured code in the CPCD portion of the decoding in ITCD.

GID also allows resolved chosen bits to be punctured back again between the Nₐth and N_{b}th iteration, if the sign of the likelihood value of any already resolved chosen bit happens to flip again. It is seen that in GID, chosen bits are resolved gradually over a span of iterations starting from the Nₐth iteration to the N_{b}th iteration as they become reliable. However, at the N_{b}th iteration, any remaining chosen bits that are not resolved are resolved based on the likelihood values of the chosen bits at the end of that N_{b}th iteration. If desired, N_{b} can be chosen to be the total number of iterations employed in the decoding. It is seen that GID is equivalent to ID, when Nₐ=N_{b}, where all chosen bits are resolved after the Nath iteration. Following the above description, the decoding steps in GID can be summarized as follows:
1. In every iteration starting from the Nₐth iteration, identify chosen bits with Lᵢ, i=1, 2, . . . , l values that maintain the same sign over the previous A iterations and complete steps 2 through 4 as described earlier to include those chosen bits for future iterations.
2. Continue step (1) up to the N_{b}th iteration or until fi values of all chosen bits have completed step 4 and the corresponding chosen bits are included in the iterations. However, if all l chosen bits have not completed steps 2 through 4 at the end of the N_{b}th iteration, perform those steps for all remaining chosen bits using the Li, i=1, 2, . . . , l values available at the end of that N_{b}th iteration.
3. In ITBF, continue decoding of C as a full code for additional N_{c} iterations. In ITCD, start CPCD iterations after N_{d} iterations and use Nₑ iterations for each punctured code in parallel.

The total number of iterations in ITBF with GID, which is (N_{b}+N_{c}), can be chosen close to that of the commonly used number of iterations to maintain about the same decoding complexity and the decoding delay. Note that in ITCD, the punctured code C₂ may still be partly punctured at the beginning of CPCD iterations which occur after N_{d} iterations. Since each punctured code in CPCD uses Nₑ iterations in parallel, the total decoding time of ITCD is equivalent to using (N_{d}+Nₑ) iterations. The values of Nₐ, N_{b}, Nₑ and λ in ITBF, and Nₐ, N_{b}, N_{d}, Nₑ and λ in ITCD can be numerically selected to achieve the best possible performance.

ITCD can be further improved by importing the principle of GID to check and correct chosen bits. Specifically, every time the punctured codes exchange information to obtain updated likelihood values, the decoder can check and correct the channel values of the chosen bits based on the updated likelihood values. ITCD with this addition to continue to correct the channel information values of the chosen bits even after the completion of the GID portion, is referred to as the modified ITCD (M-ITCD). M-ITCD can be used with GID or ID the same way ITCD can be used with GID or ID.

In order to compare GID with ID, let us consider the bit error rate (BER) variation of a typical rate R mother code C used in an ITBF or an ITCD scheme along with that of a punctured code derived from C with rate Rp (>R) that is employed in ID. It is known that the punctured code with rate Rp performs worse than the mother code C. However, as the signal to noise ratio (SNR) increases, the punctured code starts to provide reasonably reliable information of its punctured bits (which are also the chosen bits) after the initial decoding. As the punctured code begins to provide more reliable information, those punctured coded bits can be corrected to perform close to that of the transmission of the explicit sequence without any flipping. As a result, once the correction process starts to function well with ID, the performance of the punctured code with rate Rₚ starts to approach that of the original mother code C with rate R after the initial decoding. Hence, ITBF or ITCD with ID attempts to make the transition from the punctured code with rate Rₚ to the mother code with rate R all at once after a pre-selected number of initial iterations. In contrast, ITBF or ITCD with GID attempts to improve the punctured code with rate Rₚ to the mother code with rate R gradually, by performing the corrections over a span of iterations and strengthening the rate Rₚ punctured code in small increments, to approach the rate R mother code between the Nₐth and the N_{b}th iteration. As a result, GID can perform better than ID. The improved performance of GID also allows the use of higher values of l thereby increasing the transmission rate on the implicit sequence.

So far, the ITBF and ITCD implicit transmission techniques have been described earlier in this disclosure which are further improved by introducing a gradual initial decoding (GID) technique to improve the initial decoding step used in those techniques. Implicit transmission techniques when combined with the GID technique discussed earlier in the present disclosure can improve the performance and increase the transmission rate on the implicit sequence.

In the discussion that follows, implicit transmission is further developed. Specifically, a generalized implicit transmission (GIT) technique that can transmit multiple independent coded implicit sequences while transmitting a single coded explicit sequence is introduced. It is described that the GIT technique allows transmission of multiple coded implicit sequences without noticeably degrading the performance of the explicit sequence and every implicit sequence. The GIT technique is presented in two parts. In part 1, the GIT technique is described, and the encoding and decoding of GIT are discussed in detail. Further, in part 2, the explicit sequence and every implicit sequence is considered as a separate independent sequence. It is demonstrated that a code constructed according to the GIT coding technique with an explicit sequence and any number of implicit sequences N using a rate R code can maintain the performance of the explicit sequence and every implicit sequence close to the performance of a rate R code in isolation.

The LDPC codes employed in the WiFi and 5G standards demonstrate that the proposed GIT technique that can handle multiple implicit sequences can significantly increase the transmission rate on implicit sequences compared with those presented earlier in the disclosure. In part 2, in contrast to considering all sequences as independent sequences, the explicit sequence and all N implicit sequences of a code constructed using the GIT technique, are collectively considered as a single code which is referred to as a GIT coding scheme and compared with traditional codes. In part 2, GIT coding schemes are analyzed and compared with existing codes. It is demonstrated in part 2 using the same LDPC codes used in the WiFi and 5G standards that are considered in part 1 that the GIT coding schemes can function as very powerful codes and they can indeed achieve transmission rates well beyond the Shannon limit.

In the discussion that follows, we generalize ITBF and ITCD techniques described earlier in the disclosure that consist of an explicit sequence and a single implicit sequence, to include an explicit sequence and any N arbitrary number of implicit sequences. Since both ITBF and ITCD techniques have the same method of generation and they differ only in their decoding, we refer to ITBF and ITCD techniques jointly as implicit transmission (IT) techniques here.

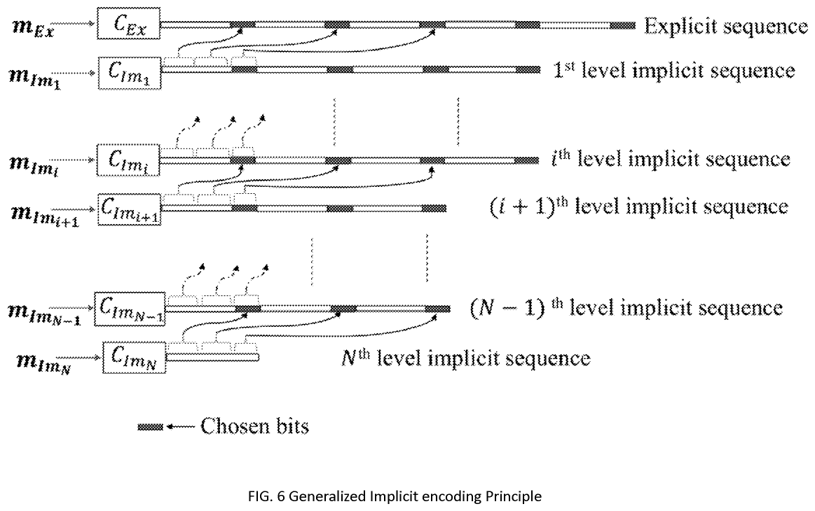

FIG. 6 illustrates the general functioning of a generalized IT (GIT) scheme. It consists of a single explicit message sequence m_{Ex} and N independent implicit message sequences m_{Imi}, i=1, . . . , N. All N implicit sequences are referred to by their corresponding level as illustrated in FIG. 6. Each of the message sequences is independently encoded to generate a coded explicit sequence v_{Ex} and N independent coded implicit sequences vImi, i=1, 2, . . . , N as illustrated in FIG. 6. Each codeword of the explicit sequence is generated by encoding a m_{Ex} bit long message sequence into a n_{Ex} bit long codeword according to the explicit code C_{Ex}. Similarly, each codeword of any ith level implicit sequence is generated by encoding a m_{Imi} bit long message sequence into a n_{Imi} bit long codeword according to the ith level implicit code C_{Imi}, i=1, 2, . . . , N. Throughout this disclosure, when referring to the implicit sequences, the 1st level is also referred to as the highest level, and the Nth level is also referred to as the lowest level.

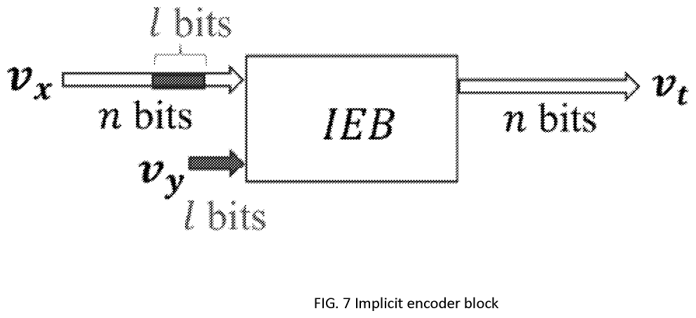

Focusing on the interactions that occur between codewords at different levels, GIT interacts between the explicit sequence and the 1st level implicit sequence. Similarly, there is interaction between every ith level implicit sequence with the (i+1)th level implicit sequence, i=1, 2, . . . , (N−1). All these interactions occur in the form of flipping as described earlier in the disclosure and illustrated in FIG. 6. As described earlier in this disclosure, every codeword on the explicit sequence selects l_{Ex} (<(n_{Ex}−m_{Ex})) number of chosen bits and flips those chosen bits according to l_{Ex} number of coded bits of the 1st level coded implicit sequence. Similarly, every codeword of the ith level coded implicit sequence selects l_{Imi} (<(n_{Imi}−m_{Imi})) number of chosen bits and flips those chosen bits according to l_{Imi} number of coded bits of the (i+1)th level coded implicit sequence, i=1, 2, . . . , (N−1). These l_{Ex} coded bits selected from the 1st level implicit sequence can preferably be selected from a single codeword of the 1st level coded implicit sequence V_{Im1}, and similarly the l_{Imi} coded bits selected from the (i+1)th level coded implicit sequence can preferably be selected from a single codeword of the (i+1)th level coded implicit sequence v_{Imi+1}. As illustrated earlier in the present disclosure, flipping l bits of any n bit long codeword vₓ according to l bits of any coded sequence v_{y} means: flip the jth bit value of the l bit long segment of vₓ, vₓ(j), from 1 to 0 and from 0 to 1 if the jth bit value of v_{y}, v_{y}(j), is a 1 (or a 0), and not flip vₓ(j) if v_{y}(j) is a 0 (or a 1), j=1, 2, . . . , l. This flipping action can be easily implemented as (vₓ+v_{y}) (mod 2) or vₓ⊕v_{y} over that l bit long segment. This operation that converts a n bit long codeword vₓ and flips its l chosen bits according to l bits of a coded sequence v_{y} and outputs the flipped n bit long sequence is represented here by a block which is referred to as an implicit encoder block (IEB) and is illustrated in FIG. 7. Note that when the explicit sequence transmits a n_{Ex} bit long flipped codeword, the 1st level implicit sequence also transmits information of l_{Ex} (<n) number of its bits implicitly. The flipping operation that occurs between the explicit sequence and the 1st level implicit sequence similarly occurs between every ith level implicit sequence according to the (i+1)th level implicit sequence as illustrated in FIGS. 6, i=1, 2, . . . , (N−1). It is noticed that the transmission rate of the 1st level implicit sequence is smaller than that of the explicit sequence. Similarly, the transmission rate of any (i+1)th level implicit sequence is smaller than that of the ith level implicit sequence, i=1, 2, . . . , (N−1). As a result, the highest transmission rate of a GIT scheme is maintained by the explicit sequence, and it gradually decreases from the 1st level implicit sequence down to the Nth level implicit sequence.

Since the GIT technique allows transmission of N independent implicit sequences while transmitting a single explicit sequence, a GIT coding scheme can be used to multiplex up to K≤(N+1) independent message sequences by assigning one or more sequences (among the explicit sequence and N implicit sequences) to a user. In contrast to a traditional multiplexed system that transmits information of each of the K users over the channel, a GIT coding scheme when used for multiplexing transmits only the explicit sequence. Therefore, on the surface, a multiplexed system constructed using the GIT technique appears to transmit only the explicit sequence, but it transmits information of all K users by transmitting some of the information explicitly on the explicit sequence and transmitting the remaining information implicitly on the N implicit sequences.

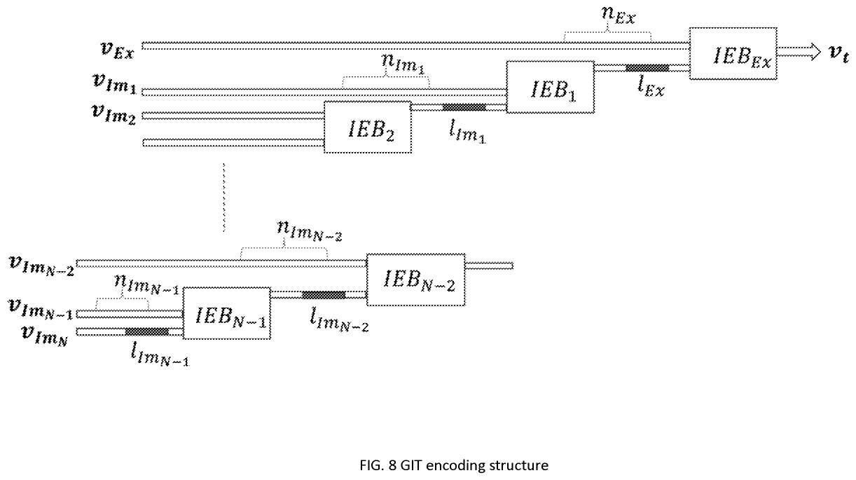

The encoding in GIT begins with the encoding of the explicit sequence according to the explicit code C_{Ex} and the encoding of all the implicit message sequences to generate their respective codewords according to their respective encoders C_{Imi}, i=1, 2, . . . , N as illustrated in FIG. 6. Then the flipping of the chosen bits of codewords at different levels begins from the (N−1)th level implicit sequence. Specifically, it divides the Nth level implicit sequence into segments of l_{ImN-1} long coded bits and feeds each of these segments into a codeword of the (N−1)th level coded implicit sequence to control the flipping of the chosen bits of that codeword of the (N−1)th level coded implicit sequence. This flipping process is continued from the (N−1)th level implicit sequence up to the 1st level implicit sequence. Specifically, every ith level implicit coded sequence is divided into segments of l_{Im(i-1)} bits and each of those segments of coded bits of the ith level implicit sequence is fed into a codeword of the (i−1)th level implicit sequence to control the flipping of the chosen bits of that codeword of the (i−1)th level implicit sequence, i=N, (N−1), (N−2), . . . , 2. FIG. 6 illustrates the flipping of implicit codewords starting from the (N−1)th level implicit sequence up to the 1st level implicit sequence. Using arrows, FIG. 6 illustrates how segments of different coded sequences are fed to the codewords of the immediately higher level coded sequence to control flipping. Once all coded implicit sequences starting from the (N−1)th level through the 1st level have completed their flipping actions, the 1st level coded implicit sequence is similarly divided into segments of length l_{Ex} bits and each of those segments is fed into a codeword of the explicit sequence to control the flipping of the chosen bits of that explicit codeword. Once the flipping on the explicit coded sequence is complete, that flipped explicit sequence is transmitted over the channel. Note that none of the coded bits of any implicit sequence is directly transmitted over the channel and as a result, the number of transmitted coded bits is the same as if none of the implicit sequences were ever present in the system. However, the information of all implicit coded bits of all implicit sequences, from levels 1 through N are carried by the transmitted sequence. As will be described later in the present disclosure, the received signal can be used to decode codewords not only of the explicit sequence but also of the implicit sequences at all levels even though none of those implicit coded bits were ever directly transmitted over the channel. The structure of a GIT encoder can be concisely represented using multiple IEBs as illustrated in FIG. 8. A GIT encoder employs an IEB at every ith implicit sequence, i=(N−1), (N−2), . . . , l, starting from the (N−1)th level implicit sequence. Note that an IEB on any ith implicit sequence, takes in a codeword of that ith level implicit sequence (similar to vₓ in FIG. 6) and l_{Imi} bit long segment from the (i+1)th level coded implicit sequence (similar to l bits of v_{y} in FIG. 7). A GIT encoder also employs an IEB on the explicit sequence by including the coded bits of the 1st level implicit sequence to control flipping as illustrated in FIG. 8. As stated before, the transmission rate in GIT is the highest on the explicit sequence and it gradually decreases from the 1st level implicit sequence down to the Nth level implicit sequence. As a result, the number of codewords used in encoding increases from the Nth level implicit sequence up to the 1st level implicit sequence and further from the 1st level implicit sequence to the explicit sequence. Therefore, the encoder can be configured by grouping codewords at different sequences to form what is referred to here as codeword blocks. Each codeword block has the highest number of codewords on the explicit sequence and gradually lowering numbers of codewords from the 1st level implicit sequence down to the Nth level implicit sequence.

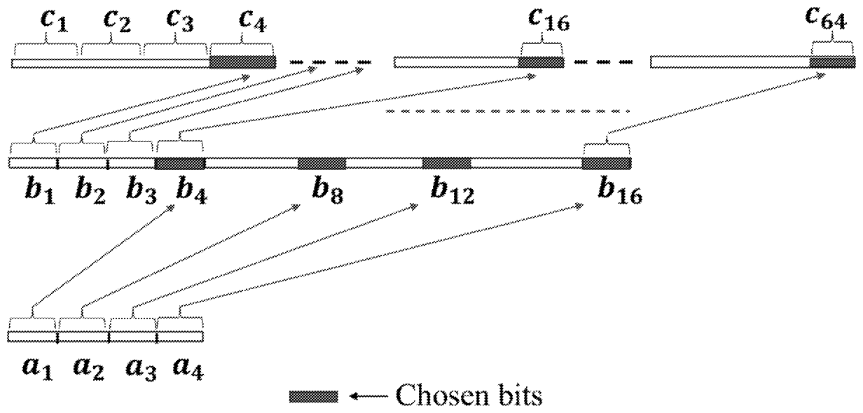

For example, consider a GIT with N=2 that employs a (n, n/2) rate ½ code on all sequences. Let us also assume that the number of chosen bits of codewords on the explicit sequence and that of the 1st implicit sequence is n/4; i.e. l=n/4. FIG. 9 illustrates how a codeword block can be formed with 16 codewords on the explicit sequence, 4 codewords on the 1st level implicit sequence, and 1 codeword on the 2nd level implicit sequence of that GIT. The n/4 segments of the codeword on the 2nd level implicit sequence are denoted by a₁, a₂, a₃ and a₄. Similarly, the n/4 segments of the four codewords on the 1st level implicit sequence are denoted by b₁ through b₁₆, and those of the sixteen codewords of the explicit sequence are denoted by c₁ through c₆₄. It is assumed that segment aⱼ, j=1, . . . , 4 of the 2nd level implicit sequence is fed to the jth codeword of the 1st level implicit sequence, and similarly the segment bₖ, k=1, 2, . . . , 16 of the 1st level implicit sequence is fed to the kth codeword of the explicit sequence in the codeword block. Using arrows, FIG. 9 illustrates how a n/4 segment of every implicit codeword is fed to control the flipping of the chosen bits of a codeword at the immediately higher level. Specifically, in the flipping of the 1st level implicit sequence, the segments b₄, b₈, b₁₂ and b₁₆ of the 1st level implicit sequence V_{Im1} are changed to (b₄⊕a₁), (b₈⊕a₂), (b₁₂⊕a₃), and (b₁₆⊕a₄) respectively. The rest of the segments in v_{Im1} remain unchanged. Similarly, Table 1 lists all changes that occur on the explicit sequence v_{Ex} due to flipping to generate the transmitted sequence vₜ while keeping all remaining segments of v_{Ex} unchanged.

TABLE 1

| | | | | | | | | | | | | | | | | |
|---|---|---|---|---|---|---|---|---|---|---|---|---|---|---|---|---|
| Before flipping | c₄ | c₈ | c₁₂ | c₁₆ | c₂₀ | c₂₄ | c₂₈ | c₃₂ | c₃₆ | c₄₀ | c₄₄ | c₄₈ | c₅₂ | c₅₆ | c₆₀ | c₆₄ |
| After flipping | c₄ + | c₈ + | c₁₂ + | c₁₆ + | c₂₀ + | c₂₄ + | c₂₈ + | c₃₂ + | c₃₆ + | c₄₀ + | c₄₄ + | c₄₈ + | c₅₂ + | c₅₆ + | c₆₀ + | c₆₄ + |
| | b₁ | b₂ | b₃ | b₄ + a₁ | b₅ | b₆ | b₇ | b₈ + a₂ | b₉ | b₁₀ | b₁₁ | b₁₂ + a₃ | b₁₃ | b₁₄ | b₁₅ | b₁₆ + a₄ |

It is seen from FIG. 9 that every codeword of the 1st level implicit sequence carries information of its own and also the information of a fourth of the codeword of the 2nd level implicit sequence. Similarly, every fourth codeword of the explicit sequence carries information of its own and additionally carries information of a fourth of a codeword of the 1st level implicit sequence along with the information that was transferred from a fourth the codeword of the 2nd level implicit sequence. Each of the remaining 12 codewords of the explicit sequence carry information of its own and the information of a fourth of a codeword of the 1st level implicit sequence without any information from the codeword of the 2nd level implicit sequence. It is noticed from FIG. 9 that the transmitted sequence of that codeword block carries information of 16 codewords of the explicit sequence, information of 4 codewords of the 1st level implicit sequence, and information of one codeword of the 2nd level implicit sequence thereby increasing the effective transmission rate of the code by 31.25% due to the use of the two implicit sequences. It follows from FIG. 9 that the transmission rate decreases by a factor of 4 from the explicit sequence to the 1st level implicit sequence and from the 1st level implicit sequence to the 2nd level implicit sequence. If desired, a 3rd level implicit sequence can be added to the codeword block in FIG. 9 by adding another sequence with 64 codewords above the explicit sequence in FIG. 9 and making that sequence with 64 codewords the explicit sequence and making the three remaining sequences below it the 1st, 2nd and the 3rd level implicit sequences respectively.

Similarly, if N=2 and 1=4n/5 (where, n is the length of a codeword) for all codewords, a codeword block can be constructed as in FIG. 9 by employing 16 codewords on the 2^{nd} implicit sequence, 20 codewords on the 1st implicit sequence, and 25 codewords on the explicit sequence.

The construction of a codeword block is fairly simple when l/n is a simple fraction as illustrated through the previous example shown in FIG. 9. However, when l/n is not a simple fraction, the approach that was presented earlier with FIG. 9 can result in codeword blocks that would require a very high number of codewords particularly at the higher levels of the codeword block. Therefore, it is desirable to have an easier way to construct codeword blocks with reasonable numbers of codewords at all levels. In practice, the explicit sequence and all N implicit sequences can be considered as sequences that take in codewords on an as needed basis. Therefore, the encoder can be implemented in practice without first constructing codeword blocks. However, when simulating the performance of a code constructed according to GIT, it is beneficial to first build a codeword block and repeat it multiple times to obtain the performance of every sequence individually. With that goal in mind, we introduce a general codeword block construction (GCBC) method using what we refer to here as supporting codewords to build a codeword block at any value of l/n and N with a reasonable number of codewords at every level. These supporting codewords are used only at the encoder to complete the flipping of all codewords that are considered at the decoder. However, supporting codewords are not decoded at the decoder or considered in the error probability calculations.

The proposed GCBC method begins with a single codeword at the lowest Nth level implicit sequence. Then find the number of codewords on every ith implicit sequence, M_{Imi}, i=N, (N−1), (N−2), . . . , l, and the number of codewords needed on the explicit sequence, M_{Ex}, iteratively. If desired, instead of using a single codeword, a higher number codewords can be used on the lowest Nth level implicit sequence at the beginning. The steps involved in the proposed GCBC method can be listed as:
1. Start with a single codeword on the Nth level implicit sequence; i.e., choose M_{ImN}=1.
2. Find M_{Im(N-1)} as

$${M}_{{Im}_{( N - 1 )}} = ⌈ {M}_{{Im}_{N}} \frac{{n}_{{Im}_{N}}}{{l}_{{Im}_{( N - 1 )}}} ⌉$$

where, ┌x┐ is the standard ceiling function of x. If

$${M}_{{Im}_{( N - 1 )}} > ⌈ {M}_{{Im}_{N}} \frac{{n}_{{Im}_{N}}}{{l}_{{Im}_{( N - 1 )}}} ⌉ ,$$

then insert a supporting codeword on the Nth level implicit sequence. Note that the supporting codeword allows all M_{Im}(N−1) number of codewords on the (N−1)th level implicit sequence to complete their flipping actions during the implicit encoding process.
3. Continue step 2 gradually from the (N−1)th level implicit sequence up to the 1st level implicit sequence by inserting supporting codewords when necessary along the way. Specifically, find the number of codewords necessary on the (i−1)th level implicit sequence, M_{Im(i-1)}, as

$${M}_{{Im}_{( i - 1 )}} = ⌈ {M}_{{Im}_{i}} \frac{{n}_{{Im}_{i}}}{{l}_{{Im}_{( i - 1 )}}} ⌉$$

and further, if

$${M}_{I {m}_{( i - 1 )}} > \text{?}$$

$$\text{?} \text{indicates text missing or illegible when filed}$$

then insert a supporting codeword on the ith level implicit sequence, i=N, (N−1), (N−2), . . . , 2.
4. Continue the same process outlined in steps 2 and 3 from the 1st level implicit sequence to the explicit sequence. Specifically, find the number of codewords necessary on the explicit sequence as

$${M}_{Ex} = ⌈ {M}_{I {m}_{1}} \frac{{n}_{I {m}_{1}}}{{l}_{Ex}} ⌉$$

and further, if

$${M}_{Ex} > ⌈ {M}_{I {m}_{1}} \frac{{n}_{I {m}_{1}}}{{l}_{Ex}} ⌉ ,$$

then insert a supporting codeword on the 1st level implicit sequence.

Hence the total number of codewords in a codeword block of a GIT that has M_{ImN} number of codewords on the Nth implicit sequence is,

$${M}_{total} = {M}_{Ex} + {\sum }_{i = 1}^{N} {M}_{I {m}_{i}} .$$

Steps 1 through 4 outlined above determine the number of codewords necessary on each level of the code constructed according to the GIT technique by placing supporting codewords when necessary in the codeword block. Note that the supporting codewords are partially used to complete flipping of all codewords that are counted in the simulation. It is also seen that the supporting codewords are not extended up to higher levels thereby maintaining a reasonable number of codewords at every level of the resulting codeword block. However, it is noticed that in continuous transmission, supporting codewords of any kth codeword block can be completed in the immediately following (k+1)th codeword block and be used in the error probability analysis. Hence in practice, only the last codeword block will need to use supporting codewords when necessary. Upon building a codeword block, the flipping can begin from the Nth level implicit sequence and move gradually up to the explicit sequence by flipping the chosen bits as described before.

For simplicity, we consider the same code is used with the same parameters on all sequences of the GIT. Specifically, we assume, C_{Ex}=C_{Imi}=C, n_{Ex}=n_{Imi}=n, i=1, 2, . . . N, and l_{Ex}=l_{Imi}=l, i=1, 2, . . . (N−1). Let us first summarize the decoding of ITBF and ITCD techniques described earlier in the present disclosure, when both the explicit and the implicit sequences employ LDPC codes, using the following steps:
1. Initial decode every explicit codeword as a punctured code by puncturing its chosen bits. This initial decoding provides likelihood values, Lᵢ, i=1, 2, . . . , l, of the l chosen bits of every codeword of the explicit sequence. A pre-selected number of iterations or the gradual initial decoding (GID) technique as discussed earlier in the disclosure that performs better than using a fixed number of initial iterations, can be used in the initial decoding.
2. Hard decode the received signal values yᵢ, i=1, 2, . . . , l, corresponding to the l chosen bits.
3. Compare the hard decoded received signal values with the signs of the likelihood values obtained in the initial decoding of the l chosen bits and determine whether each chosen bit is likely to have been flipped or not before transmission.
4. According to the decisions made in step 3, correct the channel information values corresponding to the chosen bits obtained from the received signal to match the encoded sequence before flipping.
5. In ITBF, decode the explicit code as a full code by also considering the corrected channel information values obtained in step 4 for the chosen bits. In ITCD, continue decoding as in parallel CPCD described earlier in the disclosure by considering two punctured codes; (a) the punctured code used in the initial decoding, and (b) the punctured code formed by the message bits and the corrected chosen bits found in step 4.
6. Extract artificially created channel information values for the l coded bits of the implicit sequence that were responsible in deciding whether to flip or not each of the chosen bits at the transmitter, as described earlier in the disclosure.

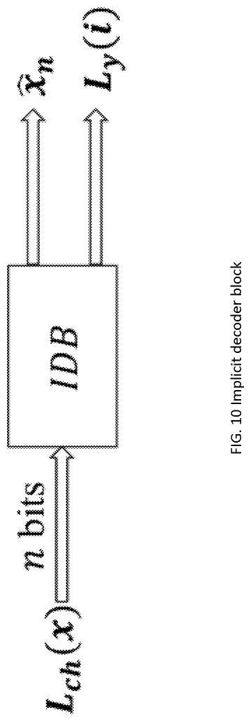

It follows from the above decoding steps that when an explicit codeword is decoded, artificially created channel information values of l number of coded bits of an implicit sequence can also be extracted. It is further noticed that artificially created channel information values are noisy similar to the channel information values extracted from a received signal that has propagated over a channel. All six steps outlined above are collectively referred to as implicit decoding and represented by an implicit decoder block (IDB) in this disclosure. Therefore, an IDB, that takes in the channel information, L_{ch}(i), i=1, 2, . . . , n, of a n-bit long explicit codeword that has been flipped over a segment of l bits according to l coded bits of an implicit sequence, can decode that explicit codeword and provide artificially created channel information of those l implicit coded bits of the implicit sequence that were responsible for flipping the chosen bits of the explicit codeword. In general, an IDB can decode a n-bit long codeword x that has undergone flipping over a portion of l coded bits according to l bits of a second coded sequence y prior to transmission, to generate the decoded codeword \hat{x} and provide artificially created channel information of l coded bits of y, L(y), as illustrated in FIG. 10. When an IDB decodes a codeword that has not undergone any flipping, it functions as a normal LDPC decoder.

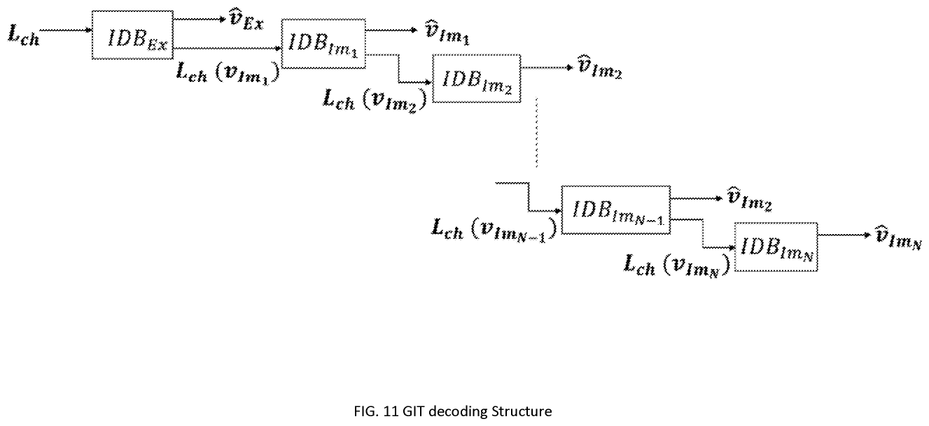

In GIT decoding, the same decoding method outlined in steps 1 through 6 and represented concisely by an IDB, is repeatedly employed to decode all codewords at every level. FIG. 11 shows the general structure of a decoder employed in a GIT to decode all codewords at every level. Specifically, the following decoding steps are used:
1. Employ an IDB for each codeword on the explicit sequence. This can be implemented either by passing all codewords of the explicit sequence in a codeword block serially through a single IDB or employing multiple IDBs to decode all codewords of the explicit sequence in parallel. This decoding provides the decoded codewords of the explicit sequence and artificially created channel information values of coded bits of the 1st level implicit sequence.
2. Decode codewords on the implicit sequences sequentially starting from the 1st level implicit sequence down to the (N−1)th level implicit sequence by following the same approach used in the decoding of the codewords on the explicit sequence. Specifically, once artificially created channel information values of all coded bits of a codeword of any ith level implicit sequence are available, pass it through an IDB to decode that codeword on that ith level implicit sequence and to provide artificially created channel information values of the corresponding l_{Imi} coded bits of the (i+1)th level implicit sequence, i=1, 2, . . . , (N−1).
3. Once all artificially created channel information values of coded bits of a codeword on the Nth level implicit sequence are available, decode that codeword using any known method of decoding. Preferably, decode each codeword of the Nth level implicit sequence either as a full code using standard decoding or decode it as in CPCD by splitting parity bits to form multiple punctured codes. It is finally noticed that, decoding can be structured in a way that decoding of lower level codewords can start decoding as soon as artificially created channel information values of codewords become available without waiting for the decoding of all codewords of the immediately higher level complete their decoding.

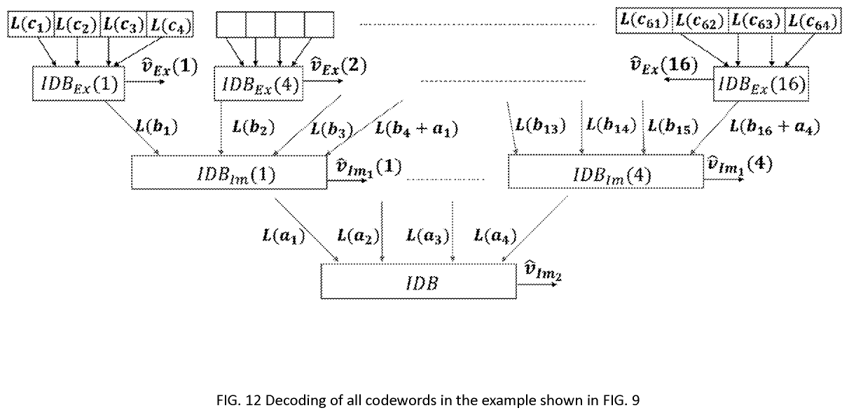

Let us consider the decoding of the codeword block shown in FIG. 9. FIG. 12 illustrates the decoding of all codewords in a codeword block shown in FIG. 9. The received signal corresponding to all 16 explicit codewords that have been flipped are passed through either a single IDB in a serial manner as illustrated in FIG. 11, or 16 different IDBs, IDBEx(i), i=1, 2, . . . , 16, in parallel as illustrated in FIG. 12. Note that the received signal corresponding to each transmitted codeword consists of four segments. For example, the four segments corresponding to the first transmitted explicit codeword are: {c1, c2, c3, (c4⊕b1)}, and those of the fourth transmitted explicit codeword are: {c13, c14, c15, (c16⊕b4⊕a1)}. Each IDB_{Ex}(i), i=1, 2, . . . , 16, provides the ith decoded explicit codeword [symbol] _{Ex}(i) and artificially created channel information of a fourth of a codeword on the 1st level implicit sequence. Additionally, every fourth IDB_{Ex}(i) provides artificially created channel information of a fourth of the codeword on the 2nd level implicit sequence too. The specific segments of the artificially created channel information values of the 1st level implicit codewords have been identified in FIG. 12. Once artificially created channel information values of all coded bits of a codeword on the 1st level implicit sequence becomes available, that codeword is similarly decoded using an IDB to obtain the decoded codeword [symbol] _{Im1}(j) of that jth 1st level coded implicit sequence as illustrated in FIG. 12. Since there are four codewords on the 1st level implicit sequence, 4 IDBs, identified as IDB_{Im1} (j), j=1, 2, 3, 4, are employed as illustrated in FIG. 12. These four IDBs on the 1st level implicit sequence decode the four codewords on the 1st level implicit sequence to obtain the decoded codewords denoted by v_{Im1}(1), . . . , v_{Im1}(4) as in FIG. 12 and to provide all artificially created channel information values of the codeword on the 2nd level implicit sequence. Finally, the 2nd level implicit codeword is decoded using the artificially created channel information values provided by all four codewords of the 1st level implicit sequence. It is seen that the decoding starts from the codewords of the explicit sequence, followed by the decoding of codewords on the 1st level implicit sequence and then to the decoding of the codeword of the 2nd level implicit sequence to obtain the 2nd level decoded sequence v_{Im2}.

So far in the present disclosure, the focus was to demonstrate that multiple independent implicit coded sequences can transmit their information implicitly (without actually transmitting over the channel) while transmitting a single coded explicit sequence over the channel. Therefore, in the disclosure above, all sequences were considered to be functioning independently. It was also demonstrated that a code constructed according to the GIT technique with a single coded explicit sequence and any number of N independent coded implicit sequences constructed using a rate R code can maintain performance similar to that of a rate R code in isolation on the explicit sequence and on each of the N implicit sequences.

We next consider the explicit sequence and all N implicit sequences jointly as a single code which is referred to here as a GIT coding scheme, or a GIT coded scheme, or simply as a GIT scheme. By considering the information carried by the explicit sequence and also the information carried by all N implicit sequences, we first introduce an overall code rate Rₒᵥₑᵣₐₗₗ for a GIT coding scheme. Note also that a GIT coding scheme with overall rate Rₒᵥₑᵣₐₗₗ functions just like a regular code with code rate Rₒᵥₑᵣₐₗₗ and transmits, on average, Rₒᵥₑᵣₐₗₗ message bits for every bit transmitted over the channel. Note that part of that information is carried explicitly by the explicit sequence transmitted over the channel while the remainder of that information is carried implicitly by the N implicit sequences. In the discussion that follows, we analyze GIT coding schemes and explain how GIT coding schemes inherently possess a coding gain due to the transmission of information implicitly over multiple implicit sequences. A simple way to convert an existing code into a powerful GIT coding scheme is also presented. It is demonstrated that due to the inherent coding gain, GIT coding schemes can reach data rates well beyond the rates that are allowed by the well-known Shannon limit.

We next analyze GIT coding schemes in detail. We first introduce an overall code rate, Rₒᵥₑᵣₐₗₗ, for a GIT coding scheme taking into account the total information carried by the explicit sequence and all implicit sequences. Then we examine the variation of Rₒᵥₑᵣₐₗₗ with the number of implicit sequences N. We also explain why a GIT coding scheme inherently possesses a coding gain due to the transmission of information implicitly.

In order to analyze the overall code rate of a GIT scheme, let us denote the following quantities: (a) the code rate of the explicit code by R_{Ex}, (b) the code rate of the implicit code of the ith level implicit sequence by R_{Imi}, i=1, 2, . . . , N, (c) the code rate of the punctured code employed during the initial decoding of the explicit sequence by R_{pEx}, and (d) the code rate of the punctured code employed during the initial decoding of the ith level implicit sequence by R_{pImi}, i=1, 2, . . . , (N−1). In order to find Rₒᵥₑᵣₐₗₗ, let us focus on (i) the number of message bits transmitted when a single codeword of every sequence is transmitted (explicitly or implicitly), and (ii) how the transmission rate on the implicit sequences 1 through N varies compared with that of the explicit sequence. First we make the following observations:
0<R_{Ex}<R_{pEx}<1 of the explicit sequence. Similarly, 0<R_{Imi}<R_{pImi}<1, i=1, 2, . . . , (N−1) of every ith implicit sequence
the number of message bits transmitted by an explicit codeword is m_{Ex}=n_{Ex}R_{Ex}.
the number of chosen bits used by a codeword on the explicit sequence is l_{Ex}=(n_{Ex}−n_{Ex} R_{Ex}/R_{pEx})=n_{Ex}(1−R_{Ex}/R_{pEx})
the number of message bits implicitly transmitted by a codeword on the ith level implicit sequence when all its coded bits are fed to the (i−1)th level implicit sequence to control flipping of the chosen bits of codewords on the (i−1)th implicit sequence is m_{Imi}=n_{Imi} R_{Imi}
the number of chosen bits used by a codeword on the ith level implicit sequence l_{Imi}=(n_{Imi}−n_{Imi} R_{Imi}/R_{pImi})=n_{Imi}(1−R_{Imi}/R_{pImi}), i=1, 2, . . . , (N−1)
the rate at which the coded bits of the ith level implicit sequence are used compared with the rate of transmission of the explicit sequence is

$${β}_{i} = ( {I}_{E x} / {n}_{E x} ) ( {\prod }_{j = 1}^{i - 1} {I}_{I m j} / {n}_{I m j} )$$

for i=2, 3, . . . , N and β₁=l_{Ex}/n_{Ex}.

Therefore, considering the total number of message bits transmitted (explicitly or implicitly) for every n_{Ex} bit long flipped explicit codeword transmitted over the channel, the overall code rate of a GIT coding scheme Rₒᵥₑᵣₐₗₗ can be expressed as

$${R}_{overall} = \frac{{m}_{Ex} + {\sum }_{i = 1}^{N} {m}_{I {m}_{i}} {β}_{i}}{{n}_{Ex}}$$

### Special Case:

Let us consider the special case when all levels use the same code and the same parameters. In this special case, let n_{Ex}=n_{Imi}=n, R_{Ex}=R_{Imi}=R for i=1, 2, . . . , N, l_{Ex}=l_{Imi}=l, and R_{pEx}=R_{pImi}=Rₚ, for i=1, 2, . . . , (N−1). Noticing that the transmission rate gradually decreases from the explicit sequence down to the Nth level implicit sequence by a factor l/n, the actual achievable overall code rate Rₒᵥₑᵣₐₗₗ of a GIT coding scheme with N implicit sequences in this special case reduces to

$${R}_{overall} = R {\sum }_{i = 0}^{N} {( \frac{l}{n} )}^{i} = R [ \frac{1 - {( l / n )}^{( N + 1 )}}{1 - ( l / n )} ] .$$

It follows from the above equation, the maximum achievable Rₒᵥₑᵣₐₗₗ value as N→∞ is (Rₒᵥₑᵣₐₗₗ)ₘₐₓ=Rn/(n−1)=Rₚ. Therefore, regardless of how low we choose the rate of the individual codes R to be, a GIT coding scheme under this special case allows the overall rate Rₒᵥₑᵣₐₗₗ to be almost equal to Rₚ. For example, if R=0.05 and Rₚ=0.5, the resulting GIT can maintain very good performance since the rate of the individual codes, R, is very low, while functioning almost as a rate ½ code by employing multiple levels of implicit sequences. Due to the simplicity of analyzing, the GIT schemes here are primarily presented under this special case. This case is referred back to as the special case throughout the remainder of this disclosure. However, it is understood that the explicit sequence and different implicit sequences can employ different code rates and different values of l/n depending on the situation.

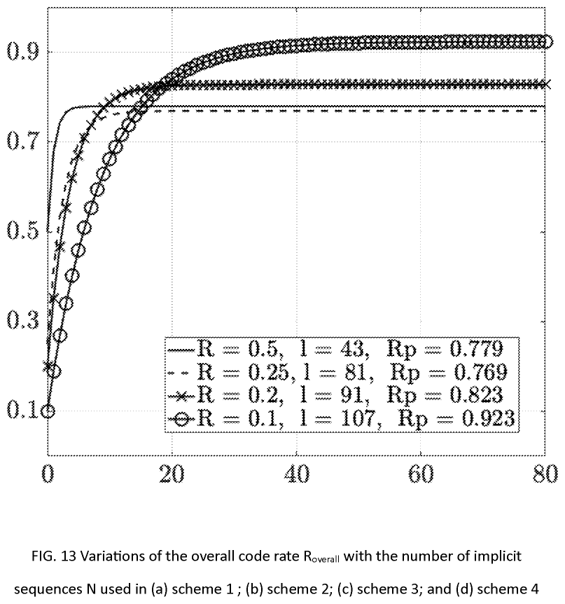

FIG. 13 shows how Rₒᵥₑᵣₐₗₗ in varies with the number of implicit sequences N in the following four GID coding schemes constructed with a code that has codeword length n=120 under the special case:
Scheme 1: R=0.5, l=43, Rₚ=0.779.
Scheme 2: R=0.25, l=81, Rₚ=0.769.
Scheme 3: R=0.2, l=91, Rₚ=0.823.
Scheme 4: R=0.1, l=107, Rₚ=0.923

FIG. 13 also depicts that the numbers of implicit sequences N needed for scheme 1, scheme 2, scheme 3 and scheme 4 to reach the Rₒᵥₑᵣₐₗₗ values 0.75, 0.75, 0.8, 0.9, are given by N=3, N=9, N=12 and N=31, respectively.

It follows from FIG. 13 that:
1. a GIT scheme can approach its respective (Rₒᵥₑᵣₐₗₗ)ₘₐₓ value as the number of implicit sequences N increases.
2. the number of implicit sequences N required to reach (Rₒᵥₑᵣₐₗₗ)ₘₐₓ increases as the l/n ratio increases. It is seen that as l/n gets closer to 1, the number of required implicit sequences to approach (Rₒᵥₑᵣₐₗₗ)ₘₐₓ increases fast.
3. at lower values of l/n, the explicit sequence usually transmits more information than the information carried by all the implicit sequences collectively. For example, in scheme 1 with N=3, the implicit sequences collectively can transmit only up to 55.8% of the transmission rate of the explicit sequence.
4. at higher values of l/n, the implicit sequences collectively can transmit more information than the information carried by the explicit sequence. For example, in scheme 4 with N=31, the implicit sequences collectively transmit 8 times more information than that of the explicit sequence. Looking at it from a different angle, the received signal provides n channel information values for every explicit codeword. The decoder uses those n channel information values, and it additionally creates on average 8n number of artificially created channel information values for codewords on the 31 implicit sequences in the decoding of the GIT coding scheme 4 with N=31 as described in this disclosure.

Let us consider a GIT coding scheme with an explicit sequence and N implicit sequences in the special case. Let us also consider that all sequences of the GIT scheme uses a rate R code and achieves an overall code rate of Rₒᵥₑᵣₐₗₗ as explained earlier in the disclosure. Therefore, when the explicit sequence transmits a single codeword of the rate R code, on average, the GIT coding scheme transmits (Rₒᵥₑᵣₐₗₗ/R) number of rate R codewords collectively on the explicit sequence and all N implicit sequences. This implies that all implicit sequences 1 through N of the GIT scheme implicitly transmit on average (Rₒᵥₑᵣₐₗₗ−R)/R number of rate R codewords for every codeword transmitted on the explicit sequence. It is mentioned here that the percentage increase in the transmission rate can also be expressed using Rₒᵥₑᵣₐₗₗ and R as n=100 (Rₒᵥₑᵣₐₗₗ−R)/R. Recall that none of the implicitly transmitted bits are actually transmitted over the channel. Therefore, implicitly transmitted bits do not require any additional transmitted power and they do not require any additional bandwidth. Therefore, a GIT coding scheme that uses a rate R code on the explicit sequence and all N implicit sequences and functions as a rate Rₒᵥₑᵣₐₗₗ code, inherently benefits a 10 log 10(Rₒᵥₑᵣₐₗₗ/R) dB coding gain. This gain achieved by a GIT coding scheme due to the transmission of information implicitly is referred to here as its inherent coding gain. Note that a GIT coding scheme with overall rate Rₒᵥₑᵣₐₗₗ functions just like a regular code with code rate Rₒᵥₑᵣₐₗₗ that transmits, on average, Rₒᵥₑᵣₐₗₗ message bits for every bit transmitted over the channel.

In order to better understand the inherent coding gain of a GIT coding scheme, let us examine the performance of a GIT coding scheme in comparison to a traditional coding scheme that employs strictly explicit transmission. Specifically, let us compare the following three codes:
(a) Code A: a traditional code with code rate R=0.1
(b) Code B: a traditional code with code rate Rₒᵥₑᵣₐₗₗ=0.8.
(c) Code C: a GIT coded scheme with N implicit sequences, constructed from code A that functions as a rate Rₒᵥₑᵣₐₗₗ=0.8 code and achieves a 10 log 10(Rₒᵥₑᵣₐₗₗ/R)=9 dB inherent coding gain

Let us compare the above three codes at the same transmitted power and the same information transfer rate. For the above comparison, let us also assume that the codeword length of codes A and B are both 100 bits long. It is well known that code A performs better than code B due to its higher coding power. In addition, it is also noticed that code A needs to increase the transmission rate compared with that of code B due to its lower code rate. Specifically, when code B transmits 80 message bits using 100 coded bits, code A needs to transmit 800 coded bits to transmit the same amount of information. This increase in the transmission rate requires code A to demand 8 times higher bandwidth than code B. This observation is in agreement with the well-known understanding that a lower rate code can achieve a higher coding gain than a higher rate code, however, at the expense of bandwidth.

Now let us compare code A with code C for the transmission of the same number of 80 message bits. Since the GIT coding scheme C is constructed from the rate R=0.1 code A, in total, both codes A and C transmit 800 coded bits to carry the information contained in 80 message bits. In code A all of those 800 coded bits are transmitted over the channel. However, in the GIT coding scheme C, the explicit sequence would carry only 100 coded bits while the remaining 700 coded bits are carried implicitly over all implicit sequences. Therefore, compared with code A, the transmission rate over the channel of code C is 8 times smaller, thereby making both codes B and C to have the same transmission rate. Hence, both codes B and C have the same bandwidth requirement, while code A demands 8 times more bandwidth. In addition, the slowing of the transmission rate of the GIT coding scheme C compared with code A, increases the effective Eb/NO value of code C by a factor 8 compared to that of code A. This increase in Eb/NO by a factor 8 benefited by the GIT coding scheme C is equivalent to a 9 dB gain over the standard rate 0.1 code A, which results in the above mentioned inherent coding gain. Therefore, code C functions very similar to code A by transmitting a total of 800 coded bits, however, transmitting only 100 coded bits over the channel while transmitting the remaining 700 coded bits implicitly using multiple implicit sequences. However, code C has the following advantages over code A: (a) it completely eliminates the bandwidth expansion of code A compared with code B, and (b) it possesses a 9 dB coding advantage over code A due to the slowing of transmission rate over the channel. On the other hand, code C functions similar to code B as they both function as rate 0.8 codes and transmit 100 coded bits over the channel to transfer the information carried by 80 message bits.

In general, a GIT coding scheme constructed from a low-rate code with code rate R to achieve an overall code rate Rₒᵥₑᵣₐₗₗ(>R), as the following advantages: (a) it eliminates the bandwidth expansion of the rate R code when compared with a rate Rₒᵥₑᵣₐₗₗ code, (b) achieves an inherent coding gain of 10 log 10(Rₒᵥₑᵣₐₗₗ/R) dB, and (c) functions as a rate Rₒᵥₑᵣₐₗₗ code.

One disadvantage of a GIT coding scheme with an explicit sequence and N implicit sequences that functions as a code with code rate Rₒᵥₑᵣₐₗₗ is that it has to decode (N+1) levels sequentially starting from the explicit sequence, and then moving down from the 1st level implicit sequence down to the last Nth level implicit sequence. This increases the decoding complexity and the decoding delay particularly for codewords on the lower level implicit sequences. Comparing with a traditional rate Rₒᵥₑᵣₐₗₗ code, a GIT coding scheme needs to decode Rₒᵥₑᵣₐₗₗ/R number of codewords, each with rate R, over the explicit sequence and over all N implicit sequences while the traditional rate Rₒᵥₑᵣₐₗₗ code decodes a single codeword. Therefore, the decoding complexity of a GIT scheme increases by a factor Rₒᵥₑᵣₐₗₗ/R when compared with a traditional rate Rₒᵥₑᵣₐₗₗ code. In addition, the decoding delay in a GIT scheme gradually increases from the explicit sequence down to the Nth level implicit sequence. Hence, when using a GIT coding scheme, the most urgent information can be transmitted on the explicit sequence. The remaining information can be selectively fed to different implicit sequences at different levels depending on their urgency as the decoding delay increases gradually from the 1st level implicit sequence down to the Nth level implicit sequence.

As stated before, it is desirable in the development of GIT coding schemes to start with low-rate codes and employ multiple implicit sequences to generate powerful GIT coding schemes. In this disclosure, we present a method to generate low-rate codes from a currently existing code without separately designing them.

Traditionally, rate adjustable coding schemes employed in practice are developed by first designing an appropriate lowrate mother code and then employing puncturing to generate other higher rate codes. In some applications, multiple codes are separately designed to be used in different situations. For example, WiFi uses a rate ½ code and a rate ¾ code, and one of these codes is selected depending on the specific application. Instead of starting from a low-rate code and developing higher rate codes from it by puncturing, we propose to generate a low-rate code starting from a good code with moderate or high code rate. The low-rate codes are constructed here from a higher rate code by using only a selected portion of the message and making the remaining message bits all zeroes, or ones, or any other pre-selected pattern of zeros and ones in the encoding process. For convenience, we consider that the selected portion of the message is forced to be zero in the remainder of this disclosure. For example, consider the rate ½ WiFi code that has code length 1944. This rate ½ code has 972 message bits and 972 parity bits. Suppose that we use only the first half of the message bits (486 bits) as the actual message and force the remaining 486 message bits to be zero in the encoding. By doing so, we use only 486 message bits out of 1944 coded bits thereby making the code effectively function as a rate ¼ code. Alternatively, we can choose not to even transmit the second half of the message portion knowing that it was forced to be zero in the encoding process, thereby using this code as a rate ⅓ code of length (1944−486)=1458 bits. Further, depending on the situation, the placement of the zeroes within the message portion, can be selected to obtain the best possible performance. In this disclosure, a low-rate code generated from a moderate rate or a high-rate code by forcing a selected set of message bits to be always zero is referred to as a derived low rate code. It is also seen that by adjusting the number of zero message bits, it is possible to easily adjust the rate of the derived low-rate code. In general, a derived low-rate code can be constructed from a (n, k) code by identifying λ(<k) number of message bits and forcing them to be zero (or any other pattern of zeros and ones) in the encoding process. Therefore, the resultant derived low-rate code can be used either (a) as a (n, k−λ) code C_{gen} with code rate R=(k−λ)/n by including the message portion that was forced to be zero in the transmission, or (b) as a (n−λ, k−λ) code C′gen with code rate (k−λ)/(n−λ) by excluding the message portion that was forced to be zero in the transmission. This (n−λ, k−λ) code is referred to here as the associate low-rate code C′gen of the (n, k−λ) derived low-rate code C_{gen}. Note that both the (n, k−λ) derived low-rate code C_{gen} and the (n−λ, k−λ) associate low-rate code C′_{gen} can be decoded using the decoder of the original (n, k) code.

Even though the above-described method of constructing a low-rate code may not be the optimal way to design low-rate codes, the construction of derived low-rate codes and their associate low-rate codes can be very helpful in practical applications as it allows a user to convert any already employed code into a low-rate code without changing that already existing encoder or the decoder. Further, as described below, the derived low-rate codes and their corresponding associate codes can be very beneficial in converting an existing coding system of any specific application into a GIT coding system without changing that already selected code in that application and instead simply making a software modification to reflect how that selected code is used according to the designed GIT coding scheme.

Let us now consider a GIT coding scheme constructed from a (n, k−λ) derived low-rate code C_{gen} and its associate (n−λ, k−λ) low rate code C′_{gen}. Since it is desirable to have a higher number of chosen bits in a GIT scheme, it is desirable to use C_{gen} on the explicit sequence by considering all or some of the A message bits, that are forced to be zero in the encoding, as part of the chosen bits.

However, when it comes to the implicit sequences, it is not clear at the first glance whether it is more desirable to use C_{gen} or C′_{gen} on the implicit sequences. On one hand, it is desirable to have a shorter code on the implicit sequences because segments of the coded bits on the implicit sequences are involved in the flipping operations as described earlier in this disclosure.

Based on that observation, the associate code C′_{gen}, which is shorter than C_{gen}, is more suitable on all implicit sequences. However, C′_{gen} has only a smaller number of parity bits (equal to (n−k)) compared with that of C_{gen} (equal to (n−k+λ)). Hence, C′_{gen} can maintain only a smaller number of chosen bits compared to the number of chosen bits of C_{gen}. Specifically, when all message bits that are forced to zero are included within the chosen bits, and the same (l−λ) number of chosen bits from the (n−k) parity bits of the original code are used by both C_{gen} and C′_{gen}, the number of chosen bits of C_{gen} is 1, whereas the number of chosen bits of C′_{gen} is (l−λ).

Let us examine the important l/n ratio of a GIT scheme that determines the spread of information among different sequences. As stated before, GIT schemes with higher values of l/n can transmit more information on implicit sequences than those with lower values of l/n, and hence, it is desirable to employ a higher value of l/n in a GIT scheme. Clearly, that l/n ratio of C_{gen} is l/n, and that of C′_{gen} is (l−λ)/(n−λ). Since n>l, the l/n ratio of C_{gen} is higher than that of C′_{gen}. Hence, considering the l/n ratio, it is more suitable to use C_{gen} from the 1st level implicit sequence down to the (N−1)th level implicit sequence. However, it can be shown that, asymptotically, the use of either C_{gen} or C′_{gen} on the implicit sequences would result in the same maximum overall code rate (Rₒᵥₑᵣₐₗₗ)ₘₐₓ as described below.

Let us focus on the number codewords transmitted by a GIT coding scheme for every single codeword transmitted over the channel when all implicit sequences employ C_{gen} and C′_{gen} separately. As discussed in the disclosure earlier, the number of codewords transmitted by a GIT scheme (which includes the explicit sequence and all N implicit sequences) for every codeword transmitted explicitly over the channel approaches l/(l−l/n)=n/(n−l) as N increases, which is equal to n/(n−l) when C_{gen} is employed on the explicit sequence and on all implicit sequences. Similarly, when C′_{gen} is used on all implicit sequences, the number of codewords transmitted implicitly for every codeword transmitted implicitly on the 1st level implicit sequence approaches to,

$$\frac{( n - λ )}{( n - λ ) - ( l - λ )} = \frac{( n - λ )}{( n - l )}$$

Further, since the length of a codeword on every implicit sequence when C′_{gen} is employed is (n−λ), the number of codewords transmitted implicitly on the 1st level implicit sequence for every codeword transmitted on the explicit sequence which employs C_{gen} that has l chosen bits is l/(n−λ). Therefore, the number of codewords transmitted by a GIT scheme for every single codeword transmitted over the channel when C_{gen} is employed on the explicit sequence and C′_{gen} is employed on all implicit sequences is, as N increases, approaches to

$$1 + ( \frac{n - λ}{n - l} ) ( \frac{l}{n - λ} ) = \frac{n}{n - l}$$

Therefore, a GIT coding scheme that employs C_{gen} on the explicit sequence and all implicit sequences, and a GIT coding scheme that employs C_{gen} on the explicit sequence and C′_{gen} on all implicit sequences approach the same (Rₒᵥₑᵣₐₗₗ)ₘₐₓ value as the number of implicit sequences N increases. Now let us focus on practical values of N. It was seen earlier in the present disclosure that the rate of convergence depends on the value of l/n. Specifically, if l/n is higher, the rate of convergence is slower, meaning that the GIT scheme would require a higher number of implicit sequences N to get close to the (Rₒᵥₑᵣₐₗₗ)ₘₐₓ. Therefore, GIT schemes that can allow only a limited number of implicit sequences, it is desirable to use C′_{gen}, that has a lower value of the ratio l/n, on all implicit sequences and use C_{gen} on the explicit sequence, than using C_{gen} on the explicit sequence and all implicit sequences.

Let us analyze a GIT coding scheme that employs C_{gen} on the explicit sequence and C′_{gen} on all N implicit sequences. As stated before C_{gen} has l chosen bits while C′_{gen} has (l−λ) chosen bits. Further, it is recalled that codewords of C_{gen} are n bits long while those of C′_{gen} are (n−λ) bits long. Following the asymptotic analysis, the total number of codewords transmitted implicitly by all N implicit sequences for every single codeword transmitted implicitly by the 1st level implicit sequence is,

$${\sum }_{i = 0}^{N - 1} {( \frac{l - λ}{n - λ} )}^{i}$$

Since l/(n−λ) number of codewords of the 1st level implicit sequence are transmitted implicitly by the 1st level implicit sequence for every codeword transmitted on the explicit sequence, the total number of codewords transmitted by this GIT coding scheme for every codeword transmitted on the explicit sequence is,

$$1 + \frac{l}{( n - λ )} {\sum }_{i = 0}^{N - 1} {( \frac{l - λ}{n - λ} )}^{i}$$

Therefore, the overall rate of the resulting GIT coding scheme when C_{gen} is used on the explicit sequence and C′_{gen} is used on all N implicit sequences is,

$${R}_{overall} = \frac{k - λ}{n} [ 1 + \frac{l}{( n - λ )} {\sum }_{i = 0}^{N - 1} {( \frac{l - λ}{n - λ} )}^{i} ]$$

In practice, the value of N can be chosen to reach the Rₒᵥₑᵣₐₗₗ value obtained according to the above equation to get close to the value of the (Rₒᵥₑᵣₐₗₗ)ₘₐₓ. Allowing N in the above equation to reach infinity, (Rₒᵥₑᵣₐₗₗ)ₘₐₓ=(k−λ)/(n−l). As stated before, (Rₒᵥₑᵣₐₗₗ)ₘₐₓ can also be found as (Rₒᵥₑᵣₐₗₗ)ₘₐₓ=Rₚ, where Rₚ is the rate of the punctured code, which in this case is again (k−λ)/(n−l). Since the Nth level implicit sequence does not experience any flipping, the best option for the Nth level implicit sequence is to use C′_{gen} instead of C_{gen} regardless of whether the other higher level implicit sequences employ C_{gen} or C′_{gen}. Hence, if a high number of implicit sequences can be tolerated, C_{gen} can be used on the explicit sequence and on implicit sequences from levels l through (N−1) while using C′_{gen} on the Nth level implicit sequence. However, in situations where the number of implicit sequences needs to be limited, it is desirable to use C_{gen} on the explicit sequence and to use C′_{gen} on all implicit sequences. Further if desired, the Nth level implicit sequence can employ the original (n, k) code without any forced zeroes in the message or any other code.

A GIT coding scheme that employs C_{gen} and/or C′_{gen} decodes according to the GIT decoding methodology described earlier in the present disclosure. The decoding starts from the explicit sequence using an IDB, and the artificially created channel information values in that decoding is passed to the 1st level implicit sequence. This process is gradually continued from the 1 st level implicit sequence down to the Nth level implicit sequence. Both codes C_{gen} and C′_{gen} can be decoded using the decoder of the original (n, k) code. In the implicit decoding of C_{gen} or C′_{gen}, the initial decoding step can include all 2 message bits that were forced to be zero at the encoder, to be considered zero and not puncture them from the beginning of that initial decoding step. In other words, only the (l−λ) chosen bits within the (n−k) parity bits are punctured in the initial decoding step. Further, the correction step within the IDB does not need to include the 2 bits within the message that were forced to be zero at the encoder. In other words, the correction step within the IDB is needed only for the (l−λ) chosen bits within the (n−k) parity bits. The method outlined herein to generate low-rate codes, allows an existing coding scheme with any code rate to be converted into a powerful GIT coding scheme without altering either the currently used encoder or the decoder.

The present disclosure will now describe an approach for designing a powerful GIT coding scheme or to convert an existing code to function as a powerful GIT coding scheme. In order to reduce complexity, it is highly desirable to use the same code and the same parameters on all sequences of a GIT coding scheme. Therefore, we focus on the design of GIT coding schemes in the special case discussed earlier in the disclosure. In addition, it is highly desirable to design GIT schemes to achieve a very high inherent coding gain 10 log 10(Rₒᵥₑᵣₐₗₗ/R) discussed earlier in the disclosure. Therefore, we focus on designing GIT schemes starting with a code with a low code rate R, and to generate GIT schemes with a high value of Rₒᵥₑᵣₐₗₗ. For example, let us revisit scheme 4 with R=0.1, and Rₒᵥₑᵣₐₗₗ=0.8 considered earlier in the disclosure in the context of FIG. 13. This resulting GIT scheme inherently possess a 9 dB coding gain. This 9 dB inherent coding gain results from the fact that the GIT scheme on average transmits 7 codewords implicitly for every codeword transmitted explicitly over the channel. However, the highest (Rₒᵥₑᵣₐₗₗ/R) value that can be practically selected depends on how bigger increase in complexity can the system tolerate. As seen from FIG. 13 discussed earlier in the disclosure, the number of required implicit sequences N increases as the value of (Rₒᵥₑᵣₐₗₗ/R) increases thereby increasing complexity. If a low rate code is not available, it is also possible to start from an existing code with a moderate rate or a high rate and choose a suitable value of 2 to generate a derived low rate code C_{gen} and its associate derived low-rate code C′_{gen} as discussed in the disclosure above.

Upon selecting a low rate with rate R and choosing a desired Rₒᵥₑᵣₐₗₗ value, choose a suitable value for Rₚ, the rate of every punctured code. Recall that the selected Rₚ value has to be bigger than the desired Rₒᵥₑᵣₐₗₗ value, Rₚ>Rₒᵥₑᵣₐₗₗ. Note that once the values of R and Rₚ are selected, the number of chosen bits l will also be known. At that point the specific locations of the chosen bits of a codeword can be selected. Then using equations derived earlier in the disclosure for (when λ=0), or (when λ>0), select the smallest value of N to ensure that the Rₒᵥₑᵣₐₗₗ value obtained is higher than the target Rₒᵥₑᵣₐₗₗ rate of the resulting GIT coding scheme.

Therefore, the design steps can be summarized as:
(a) Select a low-rate code with rate R and a desired code rate for the resulting GIT scheme Rₒᵥₑᵣₐₗₗ
(b) select a value for the punctured code Rₚ>Rₒᵥₑᵣₐₗₗ and select the chosen bits
(c) Use above equations to determine the number of required implicit sequences N

It is noted that in step (b), if the difference between R and Rₚ is very large, the resulting GIT scheme, disregarding the inherent coding gain, may undergo some performance degradation compared to that of the rate R code in isolation in order to maintain a high value of Rₚ. This degradation in performance can be reduced by employing the GID technique discussed earlier in the disclosure. However, when the inherent coding gain is accounted for, the resulting GIT coding scheme is likely to achieve a very high coding gain even though there can be a performance degradation in the GIT scheme when that inherent coding gain is disregarded. Even though the above design strategy is discussed under the special case discussed before, the same strategy with appropriate adjustments can be used to design GIT coding schemes when different sequences employ different code rates and different l/n values.

Encryption of information is a well-known technique that is widely used to secure information in digital transmission and in digital storage systems. An encryption method uses scrambling according to a specific scrambling algorithm chosen by that specific encryption method. In an encrypted data transmission system, every user uses his own secret encryption key to decrypt his message. The encrypted message is transmitted over the channel to enhance security. If an intruder is to somehow access the received signal of a user and decode the transmitted encrypted message, the intruder will still need to know the secret encryption key used by that user in order to recover the original message.

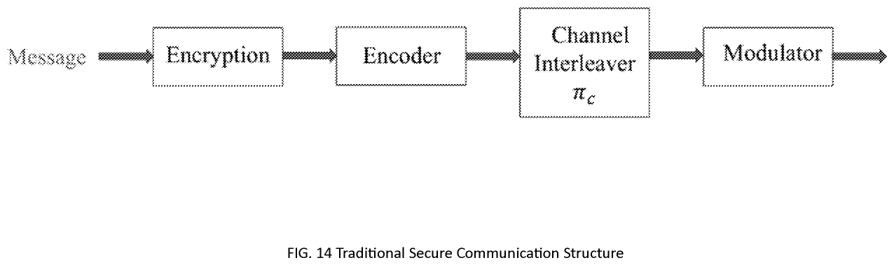

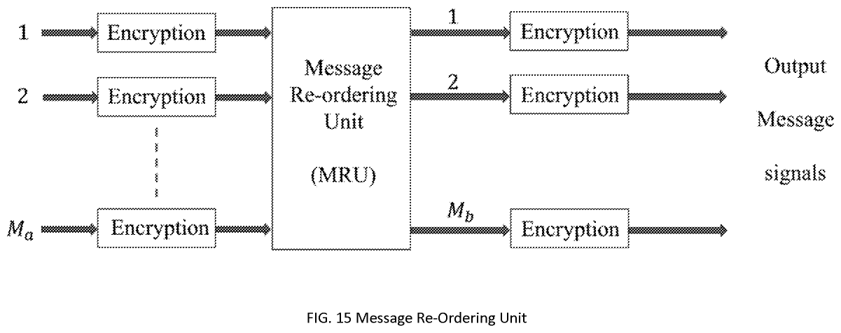

FIG. 14 illustrates the structure of a traditional communication system that transmits coded information encoded according to a code C, that enhances security by encrypting the message prior to feeding it into the encoder. The system can also use an independent channel interleaver Tc to further enhance security and to mitigate burst errors that might occur during transmission. If desired the encryption can be replaced by a message interleaver. However, as it is well known, encryption provides better protection than that provided by a simple interleaver. It is noted that, if the coded sequence is Nₑ bits long, Nₑ! different channel interleaver policies are available for the user to select one interleaving policy in the channel interleaver xc. It is realized that if an intruder who has complete knowledge of the code C accesses the received signal, cannot recover the message without knowing the exact interleaving policy employed by the channel interleaver Tc, and the secret key used by the user in the encryption process prior to transmission. Therefore, a traditional communication system can enhance security by employing encryption (or a message interleaver) and/or a channel interleaver xc in the system. We first present a general technique that can be used to enhance security in any transmission system or in a data storage system. FIG. 15 shows a message re-ordering unit (MRU) that can take in any number of Ma message signals and output any number of Mb message signals. The re-ordering can be done according to a secret reordering policy with secretly selected integer values Mₐ and M_{b} to enhance security. In addition, all message signals, both at the input and the output of the MRU can be optionally encrypted as illustrated in FIG. 15. When M_{b}=1, the MRU functions as a message combining (multiplexing) unit according to a secret combining policy. Similarly, when Mₐ=1, the MRU functions as a message splitting (de-multiplexing) unit operated according to a secret splitting policy. If desired, any preselected number of independent MRUs can be cascaded to further enhance security. In order for an intruder to recover the message, he needs to know the secret policy employed in every MRU along with the secretly selected Mₐ and M_{b} values of each MRU, and the encryption key used by every message signal within every MRU. Therefore, increasing the number of MRUs makes it harder for an intruder to access the original message thereby enhancing security.

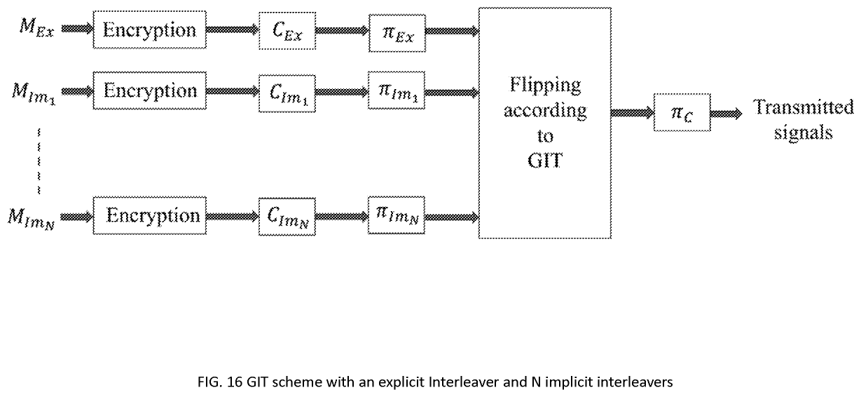

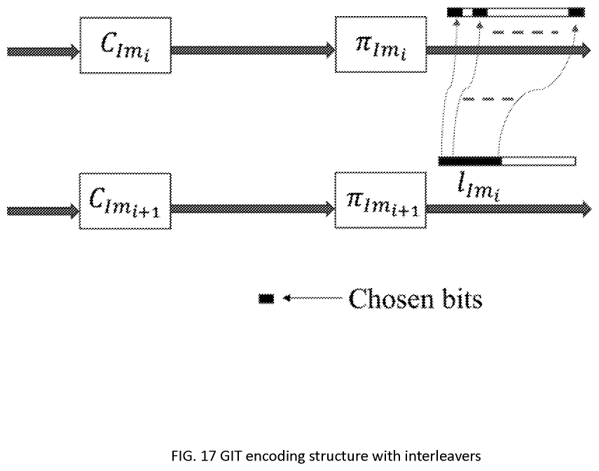

Now let us examine the security enhancement that can be achieved by using a GIT coding scheme that uses one explicit sequence and N independent implicit sequences. FIG. 16 illustrates a GIT scheme that employs an interleaver to interleave the coded sequence on the explicit sequence and independent interleavers to interleave the coded implicit sequence on every implicit sequence. The purpose of these interleavers is to spread the coded bits including the chosen bits of every codeword on every sequence according to a pre-selected secret interleaving policy. These interleaving policies can vary from channel to channel independently thereby further enhancing security. In order to reduce the decoding delay, these interleavers can preferably be selected to operate on individual codewords. For example, n_{Ex} coded bits of every codeword on the explicit sequence can be preferably interleaved according to the selected interleaver π_{Ex}. Similarly, nImi coded bits of every codeword on the ith level implicit sequence can be preferably interleaved according to the corresponding interleaver π_{Imi}, i=1, 2, . . . , N. These interleavers can instead be operated on multiple codewords by further enhancing security, however, at the expense of decoding delay. As shown in FIG. 16, interleaving is performed prior to flipping of the chosen bits that occur in a GIT scheme. Recalling the previous description of a GIT, flipping of chosen bits starts from the (N−1)th level coded implicit sequence according to the Nth level coded implicit sequence, and gradually moves up to higher sequences to finally flip the chosen bits of the explicit sequence according to the 1st level coded implicit sequence. With the presence of interleavers, flipping of bits needs to incorporate the effect of the interleavers. Specifically, the lImi chosen bits of a codeword on the ith level coded interleaved implicit sequence are flipped according to lImi number of bits of the (i+1)th level coded interleaved implicit sequence as illustrated in FIG. 17, i=(N−1), (N−2), . . . , l. The implicit encoder block (IEB), shown in FIGS. 7 and 8, employed on the ith level implicit sequence can be modified to incorporate the impact of the interleavers πImi and πImi+1 employed on the ith level implicit sequence and on the (i+1)th implicit sequence respectively. Finally, l_{Ex} chosen bits of a codeword of the coded interleaved explicit sequence are similarly flipped according to l_{Ex} number of bits of the 1st level coded interleaved implicit sequence.

At the decoder, the received channel information values corresponding to one transmitted codeword are de-interleaved according to

$${π}_{E X}^{- 1} ,$$

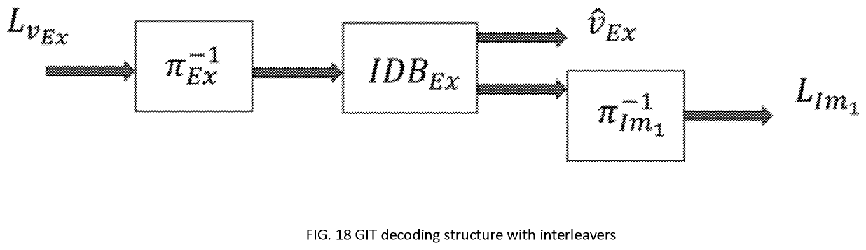

to reverse the effects of interleaving on the explicit sequence performed by TEX. This de-ineterleaved sequence is implicitly decoded using an implicit decoding block (IDB) shown in FIGS. 10 and 11 to obtain that decoded explicit codeword and to obtain lEx number of artificially created channel information values of the corresponding lEx number of bits (that were responsible for flipping of the chosen bits of that codeword at the encoder) on the 1st level coded interleaved implicit sequence as shown in FIG. 18. These artificially created channel information values are then de-interleaved according to

$${π}_{I m 1}^{- 1}$$

to undo the effects of interleaving that was performed at the encoder on the 1st level implicit sequence by π_{Im1}. Once all artificially created channel information values of a codeword of the de-interleaved sequence of the 1st level implicit sequence become available, that codeword is implicitly decoded using an IDB to decode that codeword of the implicit sequence and to generate artificially created channel information values of lIm1 number of coded bits of the 2nd level interleaved coded implicit sequence. The same process is then gradually continued down from the 1st level implicit sequence down to the (N−1)th level implicit sequence. Finally, the de-interleaved artificially created channel information values of a codeword on the Nth level implicit sequence are used to decode that codeword on the Nth level implicit sequence using any preferable decoding method. The GIT scheme enables the use of interleavers to securely transmit sensitive information. In a structure where only a fewer number of interleavers can be applied to the system, it is preferable to apply interleavers to the explicit sequence and higher level implicit sequences where artificially created channel information along with chosen bits are interleaved. Specifically, if interleaving is initiated at the explicit sequence level, and the intruder is unaware of the use of interleavers, applying the interleaver at the explicit sequence (or even at the 1st level implicit sequence), ensures the protection of all lower level information as the decoding begins at the explicit level, preventing unauthorized access to information on all levels of the transmission. The application of a limited number of encryptors can yield effective results in a similar manner.

Considering that all interleavers in FIG. 16 are designed on the basis of individual codewords (to reduce decoding delay), the number of different ways to select all interleavers shown in FIG. 16, Nᵢₙₜ, is

$${N}_{int} = {n}_{Ex} ! {\prod }_{i = 1}^{N} {n}_{I {m}_{i}} !$$

Therefore, a user can select a set of interleavers shown in FIG. 16 by choosing one of the options among all possible Nᵢₙₜ number of interleaver combinations. Therefore, in order for an intruder to recover the original message back he needs to know the exact interleaving policy of each interleaver by searching through Nᵢₙₜ number of possible interleaver selections. It is also seen that Nᵢₙₜ can be increased by an interleaver over multiple codewords (instead of single codewords as used in the above equation), however, at the expense of decoding delay. It is also noted that any number of MRUs can be used with the structure shown in FIG. 16. However, the last MRU should use M_{b}=(N+1) to be used with a GIT that employs an explicit sequence and N implicit sequences. It is further noticed that the level of security of the structure shown in FIG. 16 increases gradually from the message on the explicit sequence down to the message on the Nth implicit sequence. Therefore, in an application that employs a structure shown in FIG. 16, can deploy the most secretive information on the Nth level implicit sequence.

Now let us examine what an intruder needs to know in order to recover the message:
1. The channel interleaving policy πc
2. The interleaving policy used on the explicit sequence πEx and the interleaving policy used on every ith implicit sequence πImi, i=1, 2, . . . , N.
3. The message reordering policy used in every MRU
4. The encryption key used by every encrypted message signal in every MRU
5. In addition, the intruder also needs to know the entire GIT coding structure, which includes, the details of the code, the values of N, l_{Ex}, l_{Imi}, i=1, 2, . . . , (N−1), 2, and the locations of all chosen bits on the explicit sequence and on every ith implicit sequence, i=1, 2, . . . , (N−1).

Therefore, it is seen that the use of GIT alone makes it significantly harder for an intruder to access information. Further, the GIT structure can be used in a highly secure manner by further increasing the value of Nᵢₙₜ.

As explained before, GIT can improve performance and enhance security in a communication system. Such applications include data storage systems too. Due to hacking, it is critically important to securely store sensitive information. Due to the expanding usage of digital information formats, sensitive information is stored and transmitted in a variety of applications such as patient information in hospitals, customer information in banks, employee information in offices etc. Due to its improved performance and enhanced security, GIT can be very beneficial in storing and transmitting sensitive information. Further, as stated before, the lowest level of a GIT constructed using any N number of implicit sequences, offers the highest level of security. Therefore, the most sensitive information can be fed into the lowest (Nth) level implicit sequence or into several pre-selected lower-level implicit sequences. When a GIT is used to enhance security, the information is encoded according to the GIT technology using any desired number of encryptors and interleavers as shown in FIG. 16. In a storage system, only the explicit sequence is stored while in a transmission system, only the explicit sequence is transmitted.

The GIT technique can also be used to transmit data without first transmitting control information (also known as the header) over the channel. The control information usually needs to be transmitted with high precision in a secure manner as it contains information related to the origination and destination. In 5G, the control information is transmitted using Polar codes to improve reliability while data is transmitted using LDPC codes. However, when GIT is used, the control information can be transmitted on the implicit sequences, preferably at lower levels with enhanced security. Consider how a GIT scheme with N implicit sequences can transmit information of user A and move to transmitting information of user B without transmitting the control information of user B over the channel. During transmission of information of user A, the GIT can generate multiple encoder blocks depending on the length of user A's information. These encoder blocks can be generated using the generalized encoder block construction (GEBC) method described before and joining consecutive encoder blocks to avoid using supporting codewords in the middle encoder blocks and placing supporting codewords when necessary only in the last encoder block. For convenience, the supporting codewords that the last encoder block of a user can be made all zeros. When switching from user A to user B, the control information of user B can be included on the lower level implicit sequences of the last encoder block of user A. This control information can also include information related to the GIT technique, such as the value of N, lambda, encryption keys, interleaver information, etc. that user B intends to use next. Therefore, B can start transmitting its data starting from the very next encoder block. Therefore, the control information and information related to the GIT of the next user (such as user B) can be placed on the lower-level implicit sequences of the last encoder block of the previous user (such as user A) avoiding separate transmission of the control information over the channel. Since the lower-level implicit sequences are used to transmit data, except in the last encoder block, a pre-selected number of bits can used on those selected lower level implicit sequences (preferably at the beginning of those sequences) of every encoder block simply to identify whether those lower level implicit sequences are transmitting data or control information. For example, those pre-selected bits of those selected lower-level implicit sequences can be made zero (or one), when that encoder block is transmitting data on those lower level implicit sequences, and making those pre-selected bits of those selected lower level implicit sequences one (or zero) when those lower level implicit sequences of an encoder block are used to transmit control information. Once the receiver identifies that any current codeword block is transmitting control information on the selected lower level implicit sequences, the receiver can disregard all supporting codewords of that codeword block. However, both the encoder and the decoder need to agree on the GIT technique for the initial codeword block of the very first user. It is possible that the very first codeword block to carry information of the GIT technique of the following codeword blocks in their selected lower level implicit sequences. The same approach can also be used to switch the GIT technique when necessary, depending on the type of information transmitted. For example, if the information that is transmitted next is sensitive and needs a higher level of accuracy and protection, the GIT technique can be switched to a more secure GIT format preferably with a higher number of implicit sequences with encryptors on all sequences and feeding the most sensitive information into the lower level implicit sequences. This approach eliminates the need to transmit the control information separately over the channel. It also allows switching into different types of GIT formats depending on the need and passing the information related to the switched GIT format on the lower-level implicit sequences in the immediately previous codeword block.

While the disclosed technology is at times described above in the context of LDPC codes, it will be understood that the disclosed technology can also be applied to quantum LDPC codes.

### CONCLUSION

Example embodiments of the disclosed innovations have been described above. Those skilled in the art will understand, however, that changes and modifications may be made to the embodiments described without departing from the true scope and spirit of the present invention, which will be defined by claims.

What is claimed is:

1. A transmitter device that is configured to perform functions comprising:
encoding an explicit sequence into a set of codewords and encoding a level-ordered set of at least two implicit sequences into respective sets of implicit codewords;
based on the level-ordered set of implicit sequences, sequentially flipping, in an order beginning from a lower implicit level toward a first implicit level, respective level-defined selections of bits within respective sets of implicit codewords and thereby generating a first-level flipped implicit sequence, the first-level flipped implicit sequence including coded bits having values based on coded bits of one or more lower-level implicit sequences;
based on the coded bits of the first-level flipped implicit sequence, flipping a defined selection of bits within the set of codewords and thereby producing a flipped explicit sequence; and
transmitting the flipped explicit sequence over a communication channel.

2. The transmitter device of claim 1, wherein the explicit sequence is encoded according to an explicit code to generate the set of codewords, and wherein each implicit sequence is independently encoded according to a respective implicit code to generate the respective set of implicit codewords.

3. The transmitter device of claim 1, wherein sequentially flipping, in the order beginning from the lower implicit levels toward the first implicit level, the respective level-defined selections of bits within the respective sets of implicit codewords comprises:
for each of a plurality of implicit levels, dividing coded bits of a lower-level implicit sequence into blocks and associating each block with an implicit codeword at an immediately higher implicit level; and
bitwise modulo-2 adding the block to the respective level-defined selection of bits within the associated implicit codeword, wherein a result of the modulo-2 addition is used in a subsequent flipping operation toward the first implicit level.

4. The transmitter device of claim 1, wherein flipping the defined selection of bits within the set of codewords comprises:
dividing the first-level flipped implicit sequence into blocks each having a number of coded bits equal to a number of bits in the defined selection; and
bitwise modulo-2 adding each block to the defined selection within a respective codeword while leaving bits outside the defined selection unchanged.

5. The transmitter device of claim 1, wherein:
the flipped explicit sequence has a same number of coded bits as the encoded explicit sequence prior to the flipping; and
the implicit sequences and any flipped implicit sequences generated by the sequential flipping are not directly transmitted over the communication channel.

6. A receiver device that is configured to perform functions comprising:
receiving, over a communication channel, a signal representative of a flipped explicit sequence, wherein the flipped explicit sequence is generated from a set of codewords of a corresponding explicit sequence by flipping a defined selection of bits within the set of codewords based on coded bits of a first-level flipped implicit sequence from a level-ordered set of at least two implicit sequences;
decoding the flipped explicit sequence to recover the set of codewords of the explicit sequence;
based on decoding of the flipped explicit sequence, generating first-level artificial channel information values for the coded bits of the first-level flipped implicit sequence, wherein the first-level flipped implicit sequence is generated from a set of implicit codewords of a corresponding first-level implicit sequence by flipping a level-defined selection of bits within the set of implicit codewords based on coded bits of a next lower-level implicit sequence from the level-ordered set of implicit sequences;
beginning with the first-level flipped implicit sequence and using the first-level artificial channel information values, sequentially decoding, in an order beginning at the first implicit level and proceeding toward lower implicit levels, the implicit sequences in the level-ordered set, wherein each implicit sequence below the first implicit level is decoded using respective artificial channel information values generated based on decoding of an immediately higher-level implicit sequence; and
recovering, for each implicit sequence in the level-ordered set, a respective set of implicit codewords.

7. The receiver device of claim 6, wherein decoding the flipped explicit sequence to recover the set of codewords of the explicit sequence comprises:
initially decoding the flipped explicit sequence while treating the defined selection of bits as punctured and thereby obtaining estimated pre-flipping values for the defined selection of bits;
comparing respective received signal values corresponding to the defined selection of bits with the estimated pre-flipping values to determine respective indications of which bits in the defined selection of bits were likely flipped prior to transmission;
obtaining corrected received signal values for the defined selection of bits by, for each bit of the defined selection of bits, determining whether to change or retain the corresponding received signal value based on the respective indication of whether the bit was likely flipped prior to transmission, wherein the corresponding received signal value is changed by reversing a sign of the respective received signal value for the bit; and
decoding the flipped explicit sequence using the corrected received signal values to recover the set of codewords of the explicit sequence.

8. The receiver device of claim 7, wherein decoding the flipped explicit sequence to recover the set of codewords of the explicit sequence comprises:
decoding each flipped explicit codeword in a set of flipped explicit codewords using respective corrected received signal values, wherein each flipped explicit codeword is decoded as a full codeword using the respective corrected received signal values for the defined selection of bits and received signal values for bits outside the defined selection of bits.

9. The receiver device of claim 7, wherein generating the first-level artificial channel information values for the coded bits of the first-level flipped implicit sequence comprises:
based on the received signal values and the recovered set of codewords, generating the first-level artificial channel information values for respective coded bits of the first-level flipped implicit sequence.

10. The receiver device of claim 6, wherein decoding the flipped explicit sequence to recover the set of codewords of the explicit sequence comprises:
performing a gradual initial decoding process on flipped explicit codewords to recover the set of codewords by resolving respective bits of the defined selection of bits and correcting their corresponding received signal values over multiple decoding iterations as the respective bits satisfy reliability criteria.

11. The receiver device of claim 10, wherein a respective bit of the defined selection of bits satisfies the reliability criteria when a sign of a likelihood value for the respective bit remains unchanged over a predetermined number of decoding iterations.

12. The receiver device of claim 10, wherein the gradual initial decoding process begins resolving bits of the defined selection of bits at a predetermined starting decoding iteration and ends resolving bits of the defined selection of bits at a predetermined ending decoding iteration.

13. The receiver device of claim 6, wherein sequentially decoding the implicit sequences in the level-ordered set comprises, for each implicit level other than a lowest implicit level:
using respective artificial channel information values generated during decoding of an immediately higher-level sequence as input values for decoding of a flipped implicit sequence at the given implicit level other than the lowest implicit level;
recovering a corresponding set of implicit codewords at the given implicit level; and
generating next lower-level artificial channel information values for coded bits of an immediately lower-level flipped implicit sequence that determined flipping of the level-defined selection of bits within the respective set of implicit codewords for the implicit sequence to produce the flipped implicit sequence at the given implicit level.

14. A communication device comprising:
an encoder configured to:
encode a first explicit sequence into a first set of codewords and encode a first level-ordered set of at least two implicit sequences into respective first sets of implicit codewords;
based on the first level-ordered set of implicit sequences, sequentially flip, in an order beginning from a lower implicit level toward a first implicit level, respective first level-defined selections of bits within respective first sets of implicit codewords and thereby generate a first given first-level flipped implicit sequence, the first given first-level flipped implicit sequence including coded bits having values based on coded bits of one or more lower-level implicit sequences; and
based on the coded bits of the first given first-level flipped implicit sequence, flip a defined selection of bits within the first set of codewords and thereby produce a first flipped explicit sequence to be transmitted over a first communication channel; and
a decoder configured to:
receive, over a second communication channel, a signal representative of a second flipped explicit sequence, wherein the second flipped explicit sequence is generated from a second set of codewords of a corresponding second explicit sequence by flipping a defined selection of bits within the second set of codewords based on coded bits of a second given first-level flipped implicit sequence from a second level-ordered set of at least two implicit sequences;
decode the second flipped explicit sequence to recover the second set of codewords of the second explicit sequence;
based on decoding of the second flipped explicit sequence, generate first-level artificial channel information values for the coded bits of the second given first-level flipped implicit sequence, wherein the second given first-level flipped implicit sequence is generated from a set of implicit codewords of a corresponding first-level implicit sequence by flipping a level-defined selection of bits within the second set of implicit codewords based on coded bits of a next lower-level implicit sequence from the second level-ordered set of implicit sequences;
beginning with the second given first-level flipped implicit sequence and using the first-level artificial channel information values, sequentially decode, in an order beginning at the first implicit level and proceeding toward lower implicit levels, the implicit sequences in the second level-ordered set, wherein each implicit sequence below the first implicit level is decoded using respective artificial channel information values generated based on decoding of an immediately higher-level implicit sequence; and
recover, for each implicit sequence in the second level-ordered set, a respective set of implicit codewords and thereby recover, for the second level-ordered set of implicit sequences, respective second sets of implicit codewords.

15. The communication device of claim 14, wherein a given explicit sequence and a respective level-ordered set of implicit sequences collectively represent a single message sequence.

16. The communication device of claim 15, wherein the encoder is further configured to:
encode portions of the single message sequence according to a code to generate a plurality of codewords; and
assign, according to a predetermined codeword-distribution mapping, respective codewords of the plurality of codewords to the given explicit sequence and to each respective implicit sequence of the respective level-ordered set of implicit sequences.

17. The communication device of claim 15, wherein the decoder is further configured to:
after recovering, for the single message sequence, codewords of the given explicit sequence and respective implicit codewords of implicit sequences of the respective level-ordered set of implicit sequences, combine information represented by the recovered codewords according to an inverse of a predetermined codeword-distribution mapping used during encoding to reconstruct the single message sequence.

18. The communication device of claim 14, wherein:
the encoder is further configured to, before sequentially flipping the respective first level-defined selections of bits, interleave coded bits of at least one of the first explicit sequence or one or more implicit sequences in the first level-ordered set; and
the decoder is further configured to, in connection with decoding at least one of the second flipped explicit sequence or one or more implicit sequences in the second level-ordered set, deinterleave coded bits.

19. The communication device of claim 14, further comprising a storage medium, wherein one or both of:
a representation of the first flipped explicit sequence is stored on the storage medium without separately storing representations of the implicit sequences in the first level-ordered set; or
a representation of the second flipped explicit sequence is stored on the storage medium without separately storing representations of the implicit sequences in the second level-ordered set.

20. The communication device of claim 14, wherein:
the encoder is further configured to include, in one or more lower-level implicit sequences of the first given level-ordered set associated with a final codeword block for a current user, first control information for a subsequent transmission associated with a subsequent user; and
the decoder is further configured to recover second control information for a subsequent transmission from one or more lower-level implicit sequences of the second level-ordered set and to use the recovered second control information to configure decoding of the subsequent transmission without separately receiving the second control information over the second communication channel.
